(19) United States
(12) Patent Application Publication
(10) Pub. No.: US 2015/0226892 A1
(43) Pub. Date: Aug. 13, 2015

(54) ALKALI-SOLUBLE RESIN, PHOTOSENSITIVE RESIN COMPOSITION, COLOR FILTER AND METHOD FOR MANUFACTURING THE SAME, AND LIQUID CRYSTAL DISPLAY APPARATUS

(71) Applicant: CHI MEI CORPORATION, Tainan City (TW)

(72) Inventors: Hao-Wei Liao, Kaohsiung City (TW); Yu-Jie Tsai, Tainan City (TW)

(21) Appl. No.: 14/614,377

(22) Filed: Feb. 4, 2015

(30) Foreign Application Priority Data
Feb. 13, 2014 (TW) 103104745

(51) Int. Cl. G02B 5/22; G03F 7/00; C08G 63/54; G03F 7/038

(52) U.S. Cl. CPC G02B 5/223; G03F 7/0388; G03F 7/0007; C08G 63/54

(57) ABSTRACT

An alkali-soluble resin, a photosensitive resin composition, a color filter and a method for manufacturing the same, and a liquid crystal display apparatus are provided. The photosensitive resin composition includes an alkali-soluble resin (A), a compound (B) containing an ethylenically unsaturated group, a photoinitiator (C), and an organic solvent (D). The photosensitive resin composition contains a specific alkali-soluble resin (A-1), and therefore the photosensitive resin composition has the advantages of high resolution and excellent development resistance.

### CROSS-REFERENCE TO RELATED APPLICATION

This application claims the priority benefit of Taiwan application serial no. 103104745, filed on Feb. 13, 2014. The entirety of the above-mentioned patent application is hereby incorporated by reference herein and made a part of this specification.

### BACKGROUND OF THE INVENTION

1. Field of the Invention

The invention relates to an alkali-soluble resin, a photosensitive resin composition, a color filter and a method for manufacturing the same, and a liquid crystal display apparatus. More particularly, the invention relates to a photosensitive resin composition having high resolution and excellent development resistance.

2. Description of Related Art

With the expanding market demand for imaging equipment such as the color liquid crystal display, the manufacturing techniques of the color filter are also diversifying so as to meet the market demand. The color filter is obtained by forming different hues of three colors, red (R), green (G), and blue (B) into a pixel layer on the surface of a substrate such as a glass or a plastic sheet on which a black matrix (BM) is formed.

In general, when a negative-type photosensitive coloring composition is used to form a color filter, the negative-type photosensitive coloring composition is generally coated on a substrate and developed after being irradiated by an ultraviolet light via a photomask to obtain a pattern. The pattern formed is heated and calcined such that the pattern is fixedly stuck on the substrate. A pixel pattern is thus formed. Then, the cycle is repeated with the required colors to obtain a pattern of colored coating. However, if the cycle is repeated, a larger level difference is generated in the end of each of the BM and the RGB pixels. Uneven color display is generated due to the level difference. In order to inhibit the level difference, a transparent resin layer (protective film) is used for the planarization treatment of the color filter. The protective film needs to have features such as the ability to protect the RGB colored layer, heat resistance and hardness against pressure when liquid crystals are being filled. To display hardness, Japanese Laid-Open Patent Publication No. 5-78483 discloses a photosensitive curable resin composition having a high crosslinking density. Moreover, Japanese Laid-Open Patent 10-133372 discloses that the use of a protective film composition containing an epoxy compound can improve issues thereof such as poor pattern linearity. However, the technique still has the defects of poor resolution and poor development resistance.

Moreover, as the color filter becomes lighter and thinner and has higher color saturation, the concentration of the colorant in the photosensitive colored composition needs to be increased. However, if the concentration of the colorant is increased, then the amount of resin in the photosensitive colored composition is reduced as a result. However, when the amount of resin components on the surface of the pixel layer facilitating the adhesion of the protective film is reduced, the adhesion of the pixel layer and the protective film is reduced. As a result, the protective film readily peels off from the interface with the pixel layer, thereby causing poor resolution.

Moreover, Japanese Laid-Open Patent Publication No. Sho 61-213213 and Unexamined Patent Publication No. 1-152449 disclose the use of a (meth)acrylic acid or (meth)acrylate having a carboxyl group, a maleic acid anhydride, and copolymers of other polymerizable monomers as the photosensitive composition of the alkali-soluble resin. However, the copolymers disclosed are random copolymers, and therefore the rate distribution of alkali dissolution generated in the portion irradiated with light and in the portion not irradiated with light is uneven. As a result, better resolution and development resistance cannot be readily obtained in a developing operation.

Moreover, Japanese Laid-Open Patent Publication 5-070528 discloses that an alkali-soluble photosensitive resin can be manufactured in a desired molecule by reacting an epoxy acrylate compound having a fluorene ring with an acid anhydride, thereby improving developability. However, the defects of poor resolution and poor development resistance still exist.

Moreover, with the rising demand for the light-shielding property of the black matrix, the usage amount of black pigment is increased as a result. For instance, Japanese Laid-Open Patent Publication No. 2006-259716 discloses a photosensitive resin composition for a black matrix. The photosensitive resin composition uses a reactive monomer having two functional groups to improve the reaction between each component in the photosensitive resin composition for a black matrix, thereby forming a fine pattern. Accordingly, when the light-shielding property of the black matrix is increased by increasing the usage amount of the black pigment, the sensitivity of the photosensitive resin composition can still be maintained. However, the resolution and the development resistance thereof still cannot meet the demand of the industry.

Therefore, how to improve the resolution and the development resistance of the photosensitive resin composition at the same time so as to meet the need of the current industry is an issue that those skilled in the art urgently need to solve.

### SUMMARY OF THE INVENTION

Accordingly, the invention provides an alkali-soluble resin (A-1) for a liquid crystal display apparatus and a photosensitive resin composition using the alkali-soluble resin (A-1). The photosensitive resin composition is capable of improving the issues of poor resolution and development resistance.

The invention provides an alkali-soluble resin (A-1) represented by formula (1):

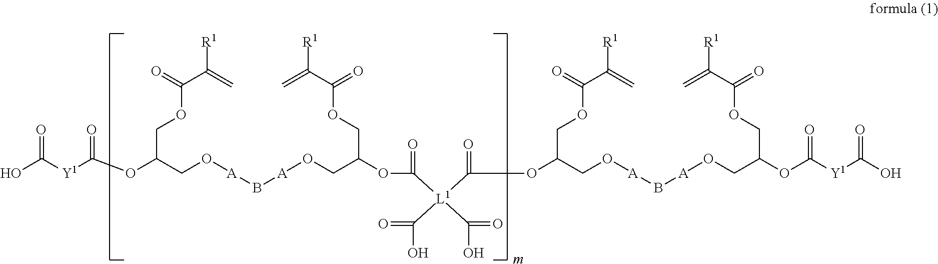

In formula (1), A represents a phenylene group or a phenylene group having a substituent, wherein the substituent is a C₁ to C₅ alkyl group, a halogen atom, or a phenyl group; B represents —CO—, —SO₂—, —C(CF₃)₂—, —Si(CH₃)₂—, —CH₂—, —C(CH₃)₂—, —O—, 9,9-fluorenylidene, or a single bond; L¹ represents a tetravalent carboxylic acid residue containing a fluorine atom or a tetravalent carboxylic acid residue without a fluorine atom; Y¹ represents a divalent carboxylic acid residue containing a fluorine atom or a divalent carboxylic acid residue without a fluorine atom; R¹ represents a hydrogen atom or a methyl group; m represents an integer of 1 to 20; and at least one of L¹ and Y¹ contains a fluorine atom.

In an embodiment of the invention, the alkai-soluble resin (A-1) is obtained by reacting a first mixture, and the first mixture includes a diol compound (a-1) containing a polymeric unsaturated group, a tetracarboxylic acid or an acid dianhydride thereof (a-2), and a dicarboxylic acid or an acid anhydride thereof (a-3). The tetracarboxylic acid or an acid dianhydride thereof (a-2) includes a tetracarboxylic acid or an acid dianhydride thereof (a-2-1) containing a fluorine atom, other tetracarboxylic acids or an acid dianhydride thereof (a-2-2) other than the tetracarboxylic acid or an acid dianhydride thereof (a-2-1) containing a fluorine atom, or a combination of the two. The dicarboxylic acid or an acid anhydride thereof (a-3) includes a dicarboxylic acid or an acid anhydride thereof (a-3-1) containing a fluorine atom, other dicarboxylic acid anhydrides or a dicarboxylic acid compound thereof (a-3-2) other than the dicarboxylic acid or an acid anhydride thereof (a-3-1) containing a fluorine atom, or a combination of the two. It should be mentioned that, at least one of the tetracarboxylic acid or an acid dianhydride thereof (a-2) and the dicarboxylic acid or an acid anhydride thereof (a-3) contains a fluorine atom.

Specifically, the tetracarboxylic acid or an acid dianhydride thereof (a-2-1) containing a fluorine atom is selected from the group consisting of a tetracarboxylic acid compound containing a fluorine atom represented by formula (2-1) and a tetracarboxylic acid dianhydride compound containing a fluorine atom represented by formula (2-2). In particular, the tetracarboxylic acid compound containing a fluorine atom represented by formula (2-1) and the tetracarboxylic acid dianhydride compound containing a fluorine atom represented by formula (2-2) are as shown below.

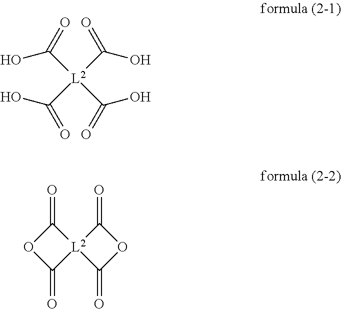

In formula (2-1) and formula (2-2), L² is selected from one of the groups represented by formula (L-1) to formula (L-6),

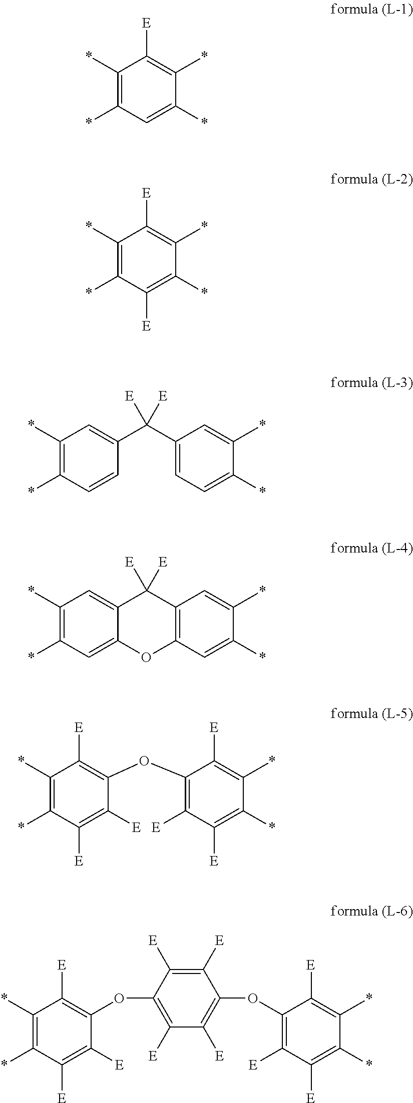

In formula (L-1) to formula (L-6), E each independently represents a fluorine atom or a trifluoromethyl group, and * represents the location of bonding with a carbon atom.

Moreover, the dicarboxylic acid or an acid anhydride thereof (a-3-1) containing a fluorine atom is selected from the group consisting of a dicarboxylic acid compound containing a fluorine atom represented by formula (3-1) and a dicarboxylic acid anhydride compound containing a fluorine atom represented by formula (3-2). In particular, the dicarboxylic acid compound containing a fluorine atom represented by formula (3-1) and the dicarboxylic acid anhydride compound containing a fluorine atom represented by formula (3-2) are as shown below.

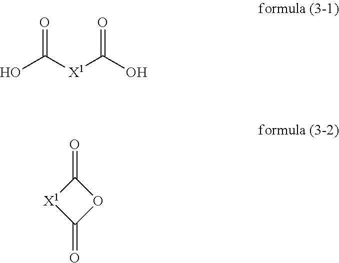

In formula (3-1) and formula (3-2), X¹ represents a C₁ to C₁₀₀ organic group containing a fluorine atom.

In an embodiment of the invention, the number of moles of the diol compound (a-1) containing a polymeric unsaturated group, the number of moles of the tetracarboxylic acid or an acid dianhydride thereof (a-2-1) containing a fluorine atom, and the number of moles of the dicarboxylic acid or an acid anhydride thereof (a-3-1) containing a fluorine atom satisfy the relationship [(a-2-1)+(a-3-1)]/(a-1)=0.2-1.8.

In an embodiment of the invention, the number of moles of the diol compound (a-1) containing a polymeric unsaturated group, the number of moles of the tetracarboxylic acid or an acid dianhydride thereof (a-2-1) containing a fluorine atom, and the number of moles of the dicarboxylic acid or an acid anhydride thereof (a-3-1) containing a fluorine atom satisfy the relationship [(a-2-1)+(a-3-1)]/(a-1)=0.3-1.7.

In an embodiment of the invention, the number of moles of the diol compound (a-1) containing a polymeric unsaturated group, the number of moles of the tetracarboxylic acid or an acid dianhydride thereof (a-2-1) containing a fluorine atom, and the number of moles of the dicarboxylic acid or an acid anhydride thereof (a-3-1) containing a fluorine atom satisfy the relationship [(a-2-1)+(a-3-1)]/(a-1)=0.4-1.6.

The invention further provides a photosensitive resin composition including an alkali-soluble resin (A), a compound (B) containing an ethylenically unsaturated group, a photoinitiator (C), and an organic solvent (D). The alkali-soluble resin (A) includes a first alkali-soluble resin (A-1) represented by formula (1):

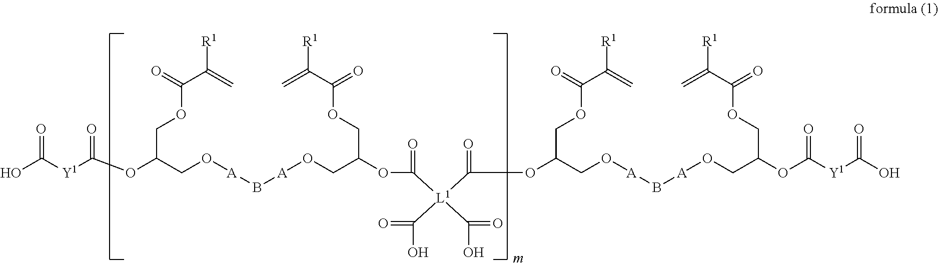

In formula (1), A represents a phenylene group or a phenylene group having a substituent, wherein the substituent is a C₁ to C₅ alkyl group, a halogen atom, or a phenyl group; B represents —CO—, —SO₂—, —C(CF₃)₂—, —Si(CH₃)₂—, —CH₂—, —C(CH₃)₂—, —O—, 9,9-fluorenylidene, or a single bond; L¹ represents a tetravalent carboxylic acid residue containing a fluorine atom or a tetravalent carboxylic acid residue without a fluorine atom; Y¹ represents a divalent carboxylic acid residue containing a fluorine atom or a divalent carboxylic acid residue without a fluorine atom; R¹ represents a hydrogen atom or a methyl group; m represents an integer of 1 to 20; and at least one of L¹ and Y¹ contains a fluorine atom.

In an embodiment of the invention, based on a usage amount of 100 parts by weight of the alkai-soluble resin (A), the usage amount of the first alkali-soluble resin (A-1) is 30 parts by weight to 100 parts by weight, the usage amount of the compound (B) containing an ethylenically unsaturated group is 20 parts by weight to 150 parts by weight, the usage amount of the photoinitiator (C) is 10 parts by weight to 90 parts by weight, and the usage amount of the organic solvent (D) is 1000 parts by weight to 7500 parts by weight.

In an embodiment of the invention, the photosensitive resin composition further includes a colorant (E).

In an embodiment of the invention, based on a usage amount of 100 parts by weight of the alkali-soluble resin (A), the usage amount of the colorant (E) is 50 parts by weight to 800 parts by weight.

The invention further provides a method for manufacturing a color filter. The method includes using the photosensitive resin composition above to form a black matrix.

The invention further provides a method for manufacturing a color filter. The method includes using the photosensitive resin composition above to form a pixel layer.

The invention further provides a method for manufacturing a color filter. The method includes using the photosensitive resin composition above to form a protective film.

The invention further provides a color filter. The color filter is obtained by the method for manufacturing a color filter above.

The invention further provides a liquid crystal display apparatus. The liquid crystal display apparatus includes the color filter above.

Based on the above, since the photosensitive resin composition of the invention uses an alkali-soluble resin (A-1) having an aromatic structure having fluorine and a specific structure, when the photosensitive resin composition is used for forming a color filter, the issues of poor resolution and development resistance can be improved at the same time. As a result, the photosensitive resin composition is suitable for the manufacture of a black matrix, a pixel layer, and a protective film of a color filter.

In order to make the aforementioned features and advantages of the disclosure more comprehensible, embodiments are described in detail below.

### DESCRIPTION OF THE EMBODIMENTS

In the following, (meth)acrylic acid represents acrylic acid and/or methacrylic acid, and (meth)acrylate represents acrylate and/or methacrylate. Similarly, (meth)acryloyl group represents acryloyl group and/or methacryloyl group.

### <Alkai-Soluble Resin>

The invention provides an alkali-soluble resin (A-1) represented by formula (1):

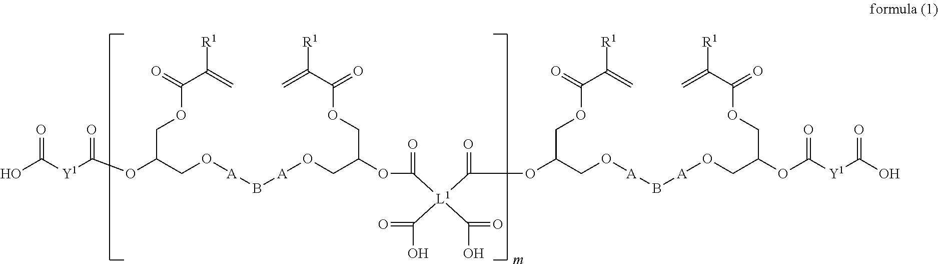

In formula (1), A represents a phenylene group or a phenylene group having a substituent, wherein the substituent is a C₁ to C₅ alkyl group, a halogen atom, or a phenyl group; B represents —CO—, —SO₂—, —C(CF₃)₂—, —Si(CH₃)₂—, —CH₂—, —C(CH₃)₂—, —O—, 9,9-fluorenylidene, or a single bond; L¹ represents a tetravalent carboxylic acid residue containing a fluorine atom or a tetravalent carboxylic acid residue without a fluorine atom; Y¹ represents a divalent carboxylic acid residue containing a fluorine atom or a divalent carboxylic acid residue without a fluorine atom; R¹ represents a hydrogen atom or a methyl group; m represents an integer of 1 to 20; and at least one of L¹ and Y¹ contains a fluorine atom.

It should be mentioned that, L¹ can be a tetravalent carboxylic acid residue containing a fluorine atom or a tetravalent carboxylic acid residue without a fluorine atom, and is preferably a tetravalent aromatic group having fluorine, more preferably a benzene ring having fluorine.

Specifically, the alkali-soluble resin (A-1) is obtained by reacting a first mixture. The first mixture includes a diol compound (a-1) containing a polymeric unsaturated group, a tetracarboxylic acid or an acid dianhydride thereof (a-2), and a dicarboxylic acid or an acid anhydride thereof (a-3). At least one of the tetracarboxylic acid or an acid dianhydride thereof (a-2) and the dicarboxylic acid or an acid anhydride thereof (a-3) needs to contain a fluorine atom. Each component of the first mixture is described below.

Diol Compound (a-1) Containing a Polymeric Unsaturated Group

The diol compound (a-1) containing a polymeric unsaturated group is obtained by reacting a bisphenol compound (a-1-i having two epoxy groups and a compound (a-1-ii) having at least one carboxylic acid group and at least one ethylenically unsaturated group. The reactants used to synthesize the diol compound (a-1) containing a polymeric unsaturated group can also contain other compounds.

The bisphenol compound (a-1-i having two epoxy groups can, for instance, be obtained by reacting a bisphenol compound and an epihalohydrin in a dehydrohalogenation reaction under the existence of an alkali metal hydroxide.

Specific examples of the bisphenol used to synthesize the bisphenol compound (a-1-i) having two epoxy groups include, for instance, bis(4-hydroxyphenyl)ketone, bis(4-hydroxy-3,5-dimethylphenyl)ketone, bis(4-hydroxy-3,5-dichlorophenyl)ketone, bis(4-hydroxyphenyl)sulfone, bis(4-hydroxy-3,5-dimethylphenyl)sulfone, bis(4-hydroxy-3,5-dichlorophenyl)sulfone, bis(4-hydroxyphenyl)hexafluoropropane, bis(4-hydroxy-3,5-dimethylphenyl)hexafluoropropane, bis(4-hydroxy-3,5-dichlorophenyl)hexafluoropropane, bis(4-hydroxyphenyl)dimethylsilane, bis(4-hydroxy-3,5-dimethylphenyl)dimethylsilane, bis(4-hydroxy-3,5-dichlorophenyl)dimethylsilane, bis(4-hydroxyphenyl)methane, bis(4-hydroxy-3,5-dichlorophenyl)methane, bis(4-hydroxy-3,5-dibromophenyl)methane, 2,2-bis(4-hydroxyphenyl)propane, 2,2-bis(4-hydroxy-3,5-dimethylphenyl)propane, 2,2-bis (4-hydroxy-3,5-dichlorophenyl)propane, 2,2-bis(4-hydroxy-3-methylphenyl)propane, 2,2-bis(4-hydroxy-3-chlorophenyl)propane, bis(4-hydroxyphenyl)ether, bis(4-hydroxy-3,5-dimethylphenyl)ether, or bis(4-hydroxy-3,5-dichlorophenyl)ether; 9,9-bis(4-hydroxyphenyl)fluorene, 9,9-bis(4-hydroxy-3-dimethylphenyl)fluorene, 9,9-bis(4-hydroxy-3-chlorophenyl)fluorene, 9,9-bis(4-hydroxy-3-bromophenyl)fluorene, 9,9-bis(4-hydroxy-3-fluorophenyl)fluorene, 9,9-bis(4-hydroxy-3,5-dimethylphenyl)fluorene, or a combination of the compounds.

Specific examples of the epihalohydrin used to synthesize the bisphenol compound (a-1-i) having two epoxy groups include 3-chloro-1,2-epoxypropane, 3-bromo-1,2-epoxypropane, or a combination of the compounds. Based on a total equivalent of 1 equivalent of the hydroxyl group in the bisphenol compound, the usage amount of the epihalohydrin can be 1 equivalent to 20 equivalents, preferably 2 equivalents to 10 equivalents.

Specific examples of the alkali metal hydroxide include sodium hydroxide, potassium hydroxide, or a combination of the compounds. Based on a total equivalent of 1 equivalent of the hydroxyl group in the bisphenol compound, the usage amount of the alkali metal hydroxide added in the dehydrohalogenation reaction can be 0.8 equivalents to 15 equivalents, preferably 0.9 equivalents to 11 equivalents.

It should be mentioned that, before the dehydrohalogenation reaction is performed, an alkali metal hydroxide such as sodium hydroxide or potassium hydroxide can be pre-added or added during the reaction process. The operating temperature of the dehydrohalogenation reaction is 20° C. to 120° C. and the operating time thereof ranges from 1 hour to 10 hours.

In an embodiment, the alkali metal hydroxide added to the dehydrohalogenation reaction can also be an aqueous solution thereof. In the present embodiment, when an aqueous solution of the alkali metal hydroxide is continuously added in the dehydrohalogenation reaction system, water and epihalohydrin can be continuously distilled under reduced pressure or atmospheric pressure at the same time to separate and remove water, and epihalohydrin can be continuously flown back to the reaction system at the same time.

Before the dehydrohalogenation reaction is performed, a quaternary ammonium salt such as tetramethyl ammonium chloride, tetramethyl ammonium bromide, or trimethylbenzyl ammonium chloride can also be added as a catalyst. Then, at 50° C. to 150° C., the mixture is reacted for 1 hour to 5 hours, and then the alkali metal hydroxide or an aqueous solution thereof is added. Then, the mixture is reacted at a temperature of 20° C. to 120° C. for 1 hour to 10 hours to perform the dehydrohalogenation reaction.

Moreover, to facilitate the dehydrohalogenation reaction, in addition to adding an alcohol such as methanol or ethanol, an aprotic polar solvent such as dimethyl sulfone or dimethyl sulfoxide can also be added to perform the reaction. When an alcohol is used, based on a total amount of 100 wt % of the epihalohydrin, the usage amount of the alcohol can be 2 wt % to 20 wt %, preferably 4 wt % to 15 wt %. When an aprotic polar solvent is used, based on a total amount of 100 wt % of the epihalohydrin, the usage amount of the aprotic polar solvent can be 5 wt % to 100 wt %, preferably 10 wt % to 90 wt %.

After the dehydrohalogenation reaction is complete, a rinse treatment can be optionally performed. Then, the epihalohydrin, the alcohol, and the aprotic polar solvent . . . etc. are removed by using a method of heating under reduced pressure, such as at a temperature of 110° C. to 250° C. and a pressure of 1.3kPa (10mmHg).

To prevent the epoxy resin formed from containing a hydrolyzable halogen, the solution after the dehydrohalogenation reaction can be added to a solvent such as benzene, toluene, or methyl isobutyl ketone, and then an aqueous solution of an alkali metal hydroxide such as sodium hydroxide or potassium hydroxide can be added to perform the dehydrohalogenation reaction again. In the dehydrohalogenation reaction, based on a total equivalent of 1 equivalent of the hydroxyl group in the bisphenol compound, the usage amount of the alkali metal hydroxide can be 0.01 moles to 1 mole, preferably 0.05 moles to 0.9 moles. Moreover, the operating temperature of the dehydrohalogenation reaction ranges from 50° C. to 120° C. and the operating time thereof ranges from 0.5 hours to 2 hours.

After the dehydrohalogenation reaction is complete, the salt is removed through steps such as filtering and rinsing. Moreover, solvents such as benzene, toluene, and methyl isobutyl ketone can be distilled by a method of heating under reduced pressure to obtain the bisphenol compound (a1-i) having two epoxy groups.

The bisphenol compound (a1-i) having two epoxy groups is preferably a bisphenol compound having two epoxy groups represented by formula (1-1) or a polymer formed by polymerizing a bisphenol compound having two epoxy groups represented by formula (1-2) as a monomer.

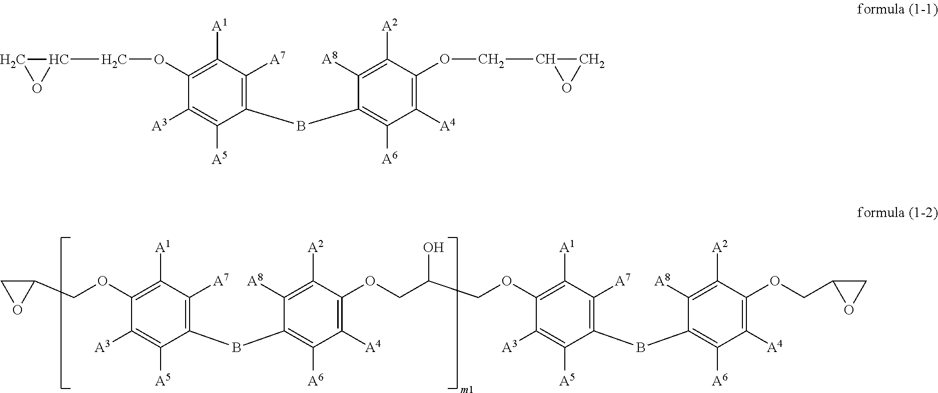

In formula (1-1) and formula (1-2), A¹ to A⁸ each independently represent a hydrogen atom, a halogen atom, a C₁ to C₅ alkyl group, or a phenyl group. B represents —CO—, —SO₂—, —C(CF₃)₂—, —Si(CH₃)₂—, —CH₂—, —C(CH₃)₂—, —O—, 9,9-fluorenylidene, or a single bond. m1 can represent an integer of 1 to 10, and m1 preferably represents an integer of 1 to 2.

The bisphenol compound having two epoxy groups represented by formula (1-1) is preferably a bisphenol compound having two epoxy groups represented by formula (1-3).

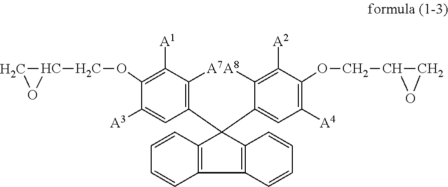

In formula (1-3), A¹, A², A³, A⁴, A⁷, and A⁸ each independently represent a hydrogen atom, a halogen atom, a C₁ to C₅ alkyl group, or a phenyl group.

The bisphenol compound having two epoxy groups represented by formula (1-3) is, for instance, a bisphenol fluorene-type compound having two epoxy groups obtained by reacting a bisphenol fluorene compound and an epihalohydrin.

Specific examples of the bisphenol fluorene-type compound include 9,9-bis(4-hydroxyphenyl)fluorene, 9,9-bis(4-hydroxy-3-methylphenyl)fluorene, 9,9-bis(4-hydroxy-3-chlorophenyl)fluorene, 9,9-bis(4-hydroxy-3-bromophenyl)fluorene, 9,9-bis(4-hydroxy-3-fluorophenyl)fluorene, 9,9-bis(4-hydroxy-3-methoxyphenyl)fluorene, 9,9-bis(4-hydroxy-3,5-dimethylphenyl)fluorene, 9,9-bis(4-hydroxy-3,5-dichlorophenyl)fluorene, 9,9-bis(4-hydroxy-3,5-dibromophenyl)fluorene, or a combination of the compounds.

Specific examples of epihalohydrin include epichlorohydrin, epibromohydrin, or a combination of the compounds.

Specific examples of the bisphenol fluorene-type compound having an epoxy group include (1) a product made by Nippon Steel Chemical such as ESF-300 or a similar compound thereof; (2) a product made by Osaka Gas such as PG-100, EG-210, or a similar compound thereof; and (3) a product made by S.M.S. Technology Co. such as SMS-F9PhPG, SMS-F9CrG, SMS-F914PG, or a similar compound thereof.

The compound (a-1-ii) having at least one carboxylic acid group and at least one ethylenically unsaturated group is at least one compound selected from the group consisting of, for instance, the following compounds: acrylic acid, methacrylic acid, 2-methacryloyloxyethylbutanedioic acid, 2-methacryloyloxybutylbutanedioic acid, 2-methacryloyloxyethylhexanedioic acid, 2-methacryloyloxybutylhexanedioic acid, 2-methacryloyloxyethylhexahydrophthalic acid, 2-methacryloyloxyethylmaleic acid, 2-methacryloyloxypropylmaleic acid, 2-methacryloyloxybutylmaleic acid, 2-methacryloyloxypropylbutanedioic acid, 2-methacryloyloxypropylhexanedioic acid, 2-methacryloyloxypropyltetrahydrophthalic acid, 2-methacryloyloxypropylphthalic acid, 2-methacryloyloxybutylphthalic acid, or 2-methacryloyloxybutylhydrophthalic acid; a compound obtained by reacting (meth)acrylate containing a hydroxyl group and a dicarboxylic acid compound, wherein the dicarboxylic acid compound contains, but is not limited to, adipic acid, succinic acid, maleic acid, or phthalic acid; and a hemiester compound obtained by reacting (meth)acrylate containing a hydroxyl group and a carboxylic acid anhydride compound, wherein the (meth)acrylate containing a hydroxyl group contains, but is not limited to, (2-hydroxyethyl)acrylate, (2-hydroxyethyl)methacrylate, (2-hydroxypropyl)acrylate, (2-hydroxypropyl)methacrylate, (4-hydroxybutyl)acrylate, (4-hydroxybutyl)methacrylate, or pentaerythritol trimethacrylate. Moreover, specific examples of the carboxylic acid anhydride compound can be the same as the specific examples of the tetracarboxylic acid dianhydride in the other tetracarboxylic acids or an acid dianhydride thereof (a-2-2) below and the specific examples of the dicarboxylic acid anhydride in the other dicarboxylic acids or an acid anhydride thereof (a-3-2) below, and are therefore not repeated herein.

Tetracarboxylic Acid or Acid Dianhydride Thereof (a-2)

The tetracarboxylic acid or an acid dianhydride thereof (a-2) includes a tetracarboxylic acid or an acid dianhydride thereof (a-2-1) containing a fluorine atom, other tetracarboxylic acids or an acid dianhydride thereof (a-2-2) other than the tetracarboxylic acid or an acid dianhydride thereof (a-2-1) containing a fluorine atom, or a combination of the two.

The tetracarboxylic acid or an acid dianhydride thereof (a-2-1) containing a fluorine atom is selected from the group consisting of a tetracarboxylic acid compound containing a fluorine atom represented by formula (2-1) and a tetracarboxylic acid dianhydride compound containing a fluorine atom represented by formula (2-2). Specifically, the tetracarboxylic acid compound containing a fluorine atom represented by formula (2-1) and the tetracarboxylic acid dianhydride compound containing a fluorine atom represented by formula (2-2) are as shown below.

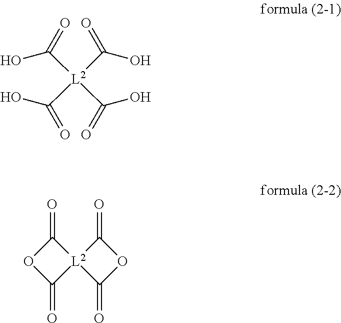

In formula (2-1) and formula (2-2), L² is a tetravalent aromatic group having fluorine and preferably has a benzene ring. Specifically, one of the groups represented by formula (L-1) to (L-6) is preferred.

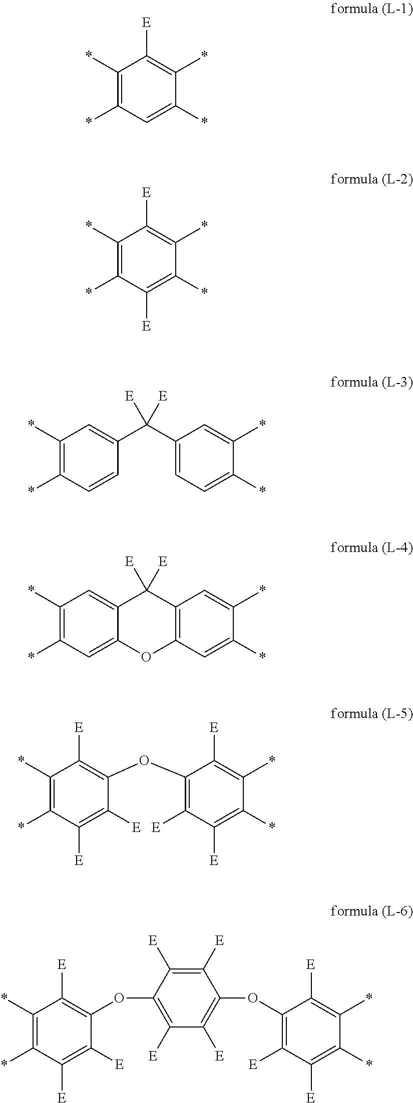

In formula (L-1) to formula (L-6), E each independently represents a fluorine atom or a trifluoromethyl group, and * represents the location of bonding with a carbon atom.

In detail, specific examples of the tetracarboxylic acid or an acid dianhydride thereof (a-2-1) containing a fluorine atom include an aromatic tetracarboxylic acid containing fluorine such as 4,4′-hexafluoro isopropylidene diphthalic acid, 1,4-difluoropyromellitic acid, 1-monofluoropyromellitic acid, 1,4-ditrifluoromethylpyromellitic acid, a dianhydride compound of the above tetracarboxylic acids, or a combination of the compounds.

Specific examples of the tetracarboxylic acid or an acid dianhydride thereof (a-2-1) containing a fluorine atom further include a tetracarboxylic acid containing fluorine such as 3,3′-(hexafluoro isopropylidene)diphthalic acid, 5,5′-[2,2,2-trifluoro-1-[3-(trifluoromethyl)phenyl]ethylidene]diphthalic acid, 5,5′-[2,2,3,3,3-pentafluoro-1-(trifluoromethyl)propylidene]diphthalic acid, 5,5′-oxybis[4,6,7-trifluoro-pyromellitic acid], 3,6-bis(trifluoromethyl)pyromellitic acid, 4-(trifluoromethyl)pyromellitic acid, 1,4-bis(3,4-dicarboxylic acid trifluorophenoxy)tetrafluoro benzene, a dianhydride compound of the above tetracarboxylic acids, or a combination of the compounds.

The other tetracarboxylic acids or an acid dianhydride thereof (a-2-2) include a saturated straight-chain hydrocarbon tetracarboxylic acid, an alicyclic tetracarboxylic acid, an aromatic tetracarboxylic acid, a dianhydride compound of the above tetracarboxylic acids, or a combination thereof.

Specific examples of the saturated straight-chain hydrocarbon tetracarboxylic acid include butanetetracarboxylic acid, pentanetetracarboxylic acid, hexanetetracarboxylic acid, or a combination of the compounds. The saturated straight-chain hydrocarbon tetracarboxylic acid can also have a substituent.

Specific examples of the alicyclic tetracarboxylic acid include cyclobutanetetracarboxylic acid, cyclopentanetetracarboxylic acid, cyclohexanetetracarboxylic acid, norbornane tetracarboxylic acid, or a combination of the compounds. The alicyclic tetracarboxylic acid can also have a substituent.

Specific examples of the aromatic tetracarboxylic acid include pyromellitic acid, benzophenone tetracarboxylic acid, biphenyl tetracarboxylic acid, biphenylether tetracarboxylic acid, diphenylsulfone tetracarboxylic acid, 1,2,3,6-tetrahydrophthalic acid, or a combination of the compounds. The aromatic tetracarboxylic acid can also have a substituent.

Dicarboxylic Acid or Acid Anhydride Thereof (a-3)

The dicarboxylic acid or an acid anhydride thereof (a-3) includes a dicarboxylic acid or an acid anhydride thereof (a-3-1) containing a fluorine atom, other dicarboxylic acids or an acid anhydride thereof (a-3-2) other than the dicarboxylic acid or an acid anhydride thereof (a-3-1) containing a fluorine atom, or a combination of the two.

The dicarboxylic acid or an acid anhydride thereof (a-3-1) containing a fluorine atom is selected from the group consisting of a dicarboxylic acid compound containing a fluorine atom represented by formula (3-1) and a dicarboxylic acid anhydride compound containing a fluorine atom represented by formula (3-2). Specifically, the dicarboxylic acid compound containing a fluorine atom represented by formula (3-1) and the dicarboxylic acid anhydride compound containing a fluorine atom represented by formula (3-2) are as shown below.

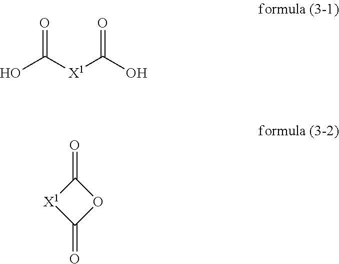

In formula (3-1) and formula (3-2), X¹ represents a C₁ to C₁₀₀ organic group containing a fluorine atom.

Specific examples of the dicarboxylic acid or an acid anhydride thereof (a-3-1) containing a fluorine atom include 3-fluorophthalic acid, 4-fluorophthalic acid, tetrafluorophthalic acid, 3,6-difluorophthalic acid, tetrafluoro succinic acid, an acid anhydride compound of the above dicarboxylic acids, or a combination of the compounds.

Specific examples of the other dicarboxylic acids or an acid anhydride thereof (a-3-2) include a saturated straight-chain hydrocarbon dicarboxylic acid, a saturated cyclic hydrocarbon dicarboxylic acid, an unsaturated dicarboxylic acid, an acid anhydride of the above dicarboxylic acid compounds, or a combination of the compounds.

Specific examples of the saturated straight-chain hydrocarbon dicarboxylic acid include succinic acid, acetyl succinic acid, adipic acid, azelaic acid, citramalic acid, malonic acid, glutaric acid, citric acid, tataric acid, ketogluconic acid, pimelic acid, sebacic acid, suberic acid, diglycolic acid, or a combination of the compounds. The hydrocarbon group in the saturated straight-chain hydrocarbon dicarboxylic acid can also be substituted.

Specific examples of the saturated cyclic hydrocarbon dicarboxylic acid include hexahydrophthalic acid, cyclobutanedicarboxylic acid, cyclopentanedicarboxylic acid, norbornanedicarboxylic acid, hexahydrotrimellitic acid, or a combination of the compounds. The saturated cyclic hydrocarbon dicarboxylic acid can also be an alicyclic dicarboxylic acid in which a saturated hydrocarbon is substituted.

Specific examples of the unsaturated dicarboxylic acid include maleic acid, itaconic acid, phthalic acid, tetrahydrophthalic acid, methyl endo-methylene tetrahydro phthalic acid, chlorendic acid, trimellitic acid, or a combination of the compounds.

Specific examples of the other dicarboxylic acids or an acid anhydride thereof (a-3-2) include a dicarboxylic acid anhydride such as trimethoxysilylpropyl succinic anhydride, triethoxysilylpropyl succinic anhydride, methyldimethoxysilylpropyl succinic anhydride, methyldiethoxysilylpropyl succinic anhydride, trimethoxysilylbutyl succinic anhydride, triethoxysilylbutyl succinic anhydride, methyldiethoxysilylbutyl succinic anhydride, para-(trimethoxysilyl)phenyl succinic anhydride, para-(triethoxysilyl)phenyl succinic anhydride, para-(methyldimethoxysilyl)phenyl succinic anhydride, para-(methyldiethoxysilyl)phenyl succinic anhydride, meta-(trimethoxysilyl)phenyl succinic anhydride, meta-(triethoxysilyl)phenyl succinic anhydride, meta-(methyldiethoxysilyl)phenyl succinic anhydride, a dicarboxylic acid compound of the above dicarboxylic acid anhydrides, or a combination of the compounds.

The dicarboxylic acid compound is preferably succinic acid, itaconic acid, tetrahydrophthalic acid, hexahydrotrimellitic acid, phthalic acid, trimellitic acid, or a combination of the compounds, and is more preferably succinic acid, itaconic acid, tetrahydrophthalic acid, or a combination of the compounds.

The dicarboxylic acid anhydride is preferably butanedioic anhydride, itaconic anhydride, tetrahydrophthalic anhydride, hexahydrotrimellitic anhydride, phthalic anhydride, trimellitic anhydride, or a combination of the compounds.

The method for synthesizing the alkali-soluble resin (A-1) is not particularly limited, and the alkali-soluble resin (A-1) can be obtained as long as the diol compound (a-1) containing a polymeric unsaturated group, the tetracarboxylic acid dianhydride or a tetracarboxylic acid thereof (a-2), and the dicarboxylic acid anhydride or a dicarboxylic acid thereof (a-3) are reacted.

When preparing the alkali-soluble resin (A-1), to speed up the reaction, an alkali compound is generally added in the reaction solution as a reaction catalyst. Specific examples of the reaction catalyst include, for instance, triphenyl phosphine, triphenyl stibine, triethylamine, triethanolamine, tetramethylammonium chloride, benzyltriethylammonium chloride, or a combination of the reaction catalysts. The reaction catalyst can be used alone or in a combination of two or more.

Moreover, to control the degree of polymerization, an inhibitor is generally added in the reaction solution. Specific examples of the inhibitor include methoxyphenol, methylhydroquinone, hydroquinone, 2,6-di-tert-butyl-p-cresol, phenothiazine, or a similar compound thereof. The inhibitor can be used alone or in a combination of two or more.

When preparing the alkali-soluble resin (A-1), a polymerization solvent can be used when needed. Specific examples of the polymerization solvent include: an alcohol compound such as ethanol, propanol, isopropanol, butanol, isobutanol, 2-butanol, hexanol, ethylene glycol, or a similar compound thereof; a ketone compound such as methyl ethyl ketone, cyclohexanone, or a similar compound thereof; an aromatic hydrocarbon compound such as toluene, xylene, or a similar compound thereof; a cellosolve compound such as cellosolve, butyl cellosolve, or a similar compound thereof; a carbitol compound such as carbitol, butyl carbitol, or a similar compound thereof; a propylene glycol alkyl ether compound such as propylene glycol monomethyl ether or a similar compound thereof; a poly(propylene glycol) alkyl ether compound such as di(propylene glycol) methyl ether or a similar compound thereof; an acetate compound such as ethyl acetate, butyl acetate, ethylene glycol monoethyl ether acetate, propylene glycol methyl ether acetate, propylene glycol methyl monoether acetate, or a similar compound thereof; an alkyl lactate compound such as ethyl lactate, butyl lactate, or a similar compound thereof; a dialkyl glycol ether; or other esters such as methyl 2-hydroxy-2-methylpropionate, ethyl 2-hydroxy-2-methylpropionate, methyl 3-methoxypropionate, ethyl 3-methoxypropionate, methyl 3-ethoxypropionate, ethyl 3-ethoxypropionate (EEP), and ethyl ethoxyacetate. The polymerization solvent can be used alone or in a combination of two or more. Moreover, the acid value of the alkali-soluble resin (A-1) is 50 mgKOH/g to 200 mgKOH/g, preferably 60 mgKOH/g to 180 mgKOH/g.

Moreover, the synthesis method can include a known method for reacting a diol compound and tetracarboxylic acid dianhydride at a reaction temperature of 90° C. to 140° C. as described in Japanese Laid-Open Patent Publication No. 9-325494. Moreover, the first mixture is uniformly dissolved and reacted at a reaction temperature of 90° C. to 130° C. and then reacted and aged at a reaction temperature of 40° C. to 80° C.

The alkali-soluble resin (A-1) obtained by reacting the first mixture is an alkali-soluble resin containing a fluorene atom, and is preferably an alkali-soluble resin containing an aromatic structure having fluorine.

Moreover, in each component of the first mixture forming the alkali-soluble resin (A-1), in the tetracarboxylic acid or an acid dianhydride thereof (a-2) and the dicarboxylic acid or an acid anhydride thereof (a-3), at least one of the two contains a fluorine atom, and preferably both the tetracarboxylic acid or an acid dianhydride thereof (a-2) and the dicarboxylic acid or an acid anhydride thereof (a-3) contain a fluorine atom. When the tetracarboxylic acid or an acid dianhydride thereof (a-2) or the dicarboxylic acid or an acid anhydride thereof (a-3) does not contain a fluorine atom, the resolution and the development resistance of the photosensitive resin composition are poor. Specifically, when both the tetracarboxylic acid or an acid dianhydride thereof (a-2) and the dicarboxylic acid or an acid anhydride thereof (a-3) contain a fluorine atom, the tetracarboxylic acid or an acid dianhydride thereof (a-2) includes the tetracarboxylic acid or an acid dianhydride thereof (a-2-1) containing a fluorine atom, and the dicarboxylic acid or an acid anhydride thereof (a-3) includes the dicarboxylic acid or an acid anhydride thereof (a-3-1) containing a fluorine atom.

Since the fluorine atom can effectively increase the alkali resistance of the alkali-soluble resin (A), the development resistance of the photosensitive resin composition is better. Moreover, due to the development resistance of the photosensitive resin composition, a finer pattern can remain on the substrate during development, thereby increasing the resolution of the photosensitive resin composition.

Moreover, the number of moles of the diol compound (a-1) containing a polymeric unsaturated group, the number of moles of the tetracarboxylic acid or an acid dianhydride thereof (a-2-1) containing a fluorine atom, and the number of moles of the dicarboxylic acid or an acid anhydride thereof (a-3-1) containing a fluorine atom can satisfy the relationship [(a-2-1)+(a-3-1)]/(a-1)=0.2-1.8, preferably satisfy the relationship [(a-2-1)+(a-3-1)]/(a-1)=0.3-1.7, and more preferably satisfy the relationship [(a-2-1)+(a-3-1)]/(a-1)=0.4-1.6. When [(a-2-1)+(a-3-1)]/(a-1)=0.2-1.8, the resolution of the photosensitive resin composition can be further increased.

### <Photosensitive Resin Composition>

The invention provides a photosensitive resin composition including an alkali-soluble resin (A), a compound (B) containing an ethylenically unsaturated group, a photoinitiator (C), and an organic solvent (D). Moreover, if needed, the photosensitive resin composition can further include one or both of a colorant (E) and an additive (F). In the following, the individual components used in the photosensitive resin composition of the invention are described in detail.

### Alkai-Soluble Resin (A)

The alkali-soluble resin (A) includes a first alkali-soluble resin (A-1). Moreover, the alkali-soluble resin (A) can optionally include a second alkai-soluble resin (A-2) and other alkali-soluble resins (A-3).

### First Alkai-Soluble Resin (A-1)

The first alkali-soluble resin (A-1) is a compound represented by formula 1:

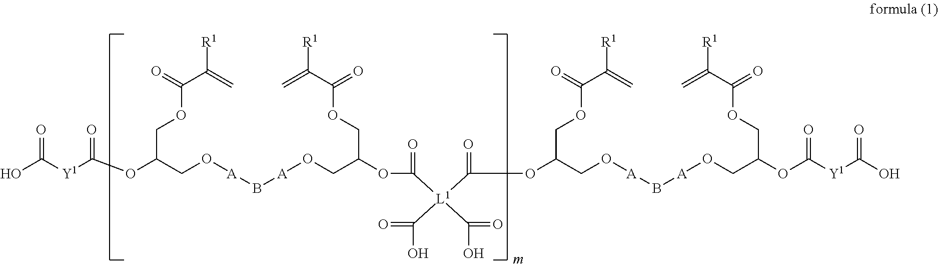

In formula (1), A represents a phenylene group or a phenylene group having a substituent, wherein the substituent is a C₁ to C₅ alkyl group, a halogen atom, or a phenyl group; B represents —CO—, —SO₂—, —C(CF₃)₂—, —Si(CH₃)₂—, —CH₂—, —C(CH₃)₂—, —O—, 9,9-fluorenylidene, or a single bond; L¹ represents a tetravalent carboxylic acid residue containing a fluorine atom or a tetravalent carboxylic acid residue without a fluorine atom; Y¹ represents a divalent carboxylic acid residue containing a fluorine atom or a divalent carboxylic acid residue without a fluorine atom; R¹ represents a hydrogen atom or a methyl group; m represents an integer of 1 to 20; and at least one of L¹ and Y¹ contains a fluorine atom.

Here, the first alkali-soluble resin (A-1) represented by formula (1) is as described above and is not repeated herein.

It should be mentioned that, when the photosensitive resin composition contains the first alkali-soluble resin (A-1), since the fluorine atom can effectively increase the alkali resistance of the alkali-soluble resin, the development resistance of the photosensitive resin composition is better. Moreover, due to the development resistance of the photosensitive resin composition, a finer pattern can remain on the substrate during development, thereby increasing the resolution of the photosensitive resin composition.

Moreover, the number of moles of the diol compound (a-1) containing a polymeric unsaturated group, the number of moles of the tetracarboxylic acid or an acid dianhydride thereof (a-2-1) containing a fluorine atom, and the number of moles of the dicarboxylic acid or an acid anhydride thereof (a-3-1) containing a fluorine atom can satisfy the relationship [(a-2-1)+(a-3-1)]/(a-1)=0.2-1.8, preferably satisfy the relationship [(a-2-1)+(a-3-1)]/(a-1)=0.3-1.7, and more preferably satisfy the relationship [(a-2-1)+(a-3-1)]/(a-1)=0.4-1.6. When [(a-2-1)+(a-3-1)]/(a-1)=0.2-1.8, the resolution of the photosensitive resin composition can be further increased.

Based on a usage amount of 100 parts by weight of the alkai-soluble resin (A), the usage amount of the first alkali-soluble resin (A-1) can be 30 parts by weight to 100 parts by weight, preferably 40 parts by weight to 100 parts by weight, and more preferably 50 parts by weight to 100 parts by weight. When the alkali-soluble resin (A) does not contain the first alkali-soluble resin (A-1), the resolution and the development resistance of the photosensitive resin composition are poor.

### Second Alkai-Soluble Resin (A-2)

The second alkali-soluble resin (A-2) includes a derived unit having the structure represented by formula (4):

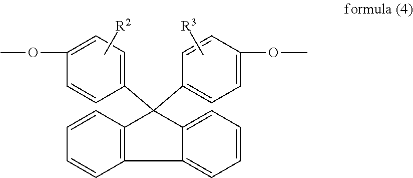

In formula (4), R² and R³ are each independently a hydrogen atom, a C₁ to C₅ straight-chain or branch-chain alkyl group, a phenyl group, or a halogen atom.

The second alkai-soluble resin (A-2) is obtained by reacting a compound having the structure represented by formula (4) and other copolymerizable compounds. The compound having the structure represented by formula (4) can be a bisphenol fluorene-type compound containing two epoxy groups represented by formula (5) or a bisphenol fluorene-type compound containing two hydroxyl groups represented by formula (6).

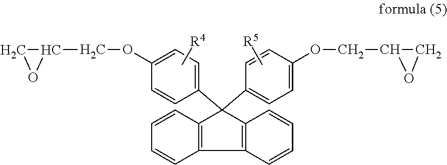

In formula (5), R⁴ is the same as R² of formula (4); and R⁵ is the same as R³ of formula (4).

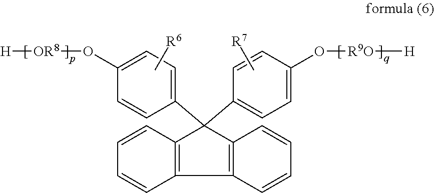

In formula (6), R⁶ is the same as R² of formula (4); R⁷ is the same as R³ of formula (4); R⁸ and R⁹ each independently represent a C₁ to C₂₀ alkylene group or alicyclic group; and p and q each independently represent an integer of 1 to 4.

Specific examples of the other copolymerizable compounds include an unsaturated monocarboxylic acid such as acrylic acid, methacrylic acid, butenoic acid, α-chloroacrylic acid, ethyl acrylic acid, or cinnamic acid; a dicarboxylic acid such as maleic acid, itaconic acid, succinic acid, phthalic acid, tetrahydrophthalic acid, hexahydrophthalic acid, methyl tetrahydrophthalic acid, methyl hexahydrophthalic acid, methyl endo-methylene tetrahydro phthalic acid, chlorendic acid, or glutaric acid, and an acid anhydride thereof; a tricarboxylic acid such as trimellitic acid and an acid anhydride thereof; and a tetracarboxylic acid such as pyromellitic acid, benzophenone tetracarboxylic acid, biphenyl tetracarboxylic acid, or biphenylether tetracarboxylic acid, an acid anhydride thereof, or a combination of the compounds.

The second alkai-soluble resin (A-2) is preferably a product made by Nippon Steel Chemical such as V259ME or V301ME.

Based on a usage amount of 100 parts by weight of the alkai-soluble resin (A), the usage amount of the second alkali-soluble resin (A-2) can be 0 parts by weight to 70 parts by weight, preferably 0 parts by weight to 60 parts by weight, and more preferably 0 parts by weight to 50 parts by weight.

### Other Alkai-Soluble Resins (A-3)

The alkali-soluble resin (A) can further optionally include other alkai-soluble resins (A-3). The other alkali-soluble resins (A-3) are resins other than the first alkali-soluble resin (A-1) and the second alkali-soluble resin (A-2). The other alkali-soluble resins (A-3) are, for instance, resins having a carboxylic acid group or a hydroxyl group, but are not limited to resins having a carboxylic acid group or a hydroxyl group. Specific examples of the other alkai-soluble resins (A-3) include a resin such as acrylic resin, urethane resin, or novolac resin.

Based on a usage amount of 100 parts by weight of the alkai-soluble resin (A), the usage amount of the other alkali-soluble resins (A-3) is 0 parts by weight to 30 parts by weight, preferably 0 parts by weight to 20 parts by weight, and more preferably 0 parts by weight to 10 parts by weight.

### Compound (B) Containing an Ethylenically Unsaturated Group

The compound (B) containing an ethylenically unsaturated group can be selected from a compound (B-1) having 1 ethylenically unsaturated group and a compound (B-2) having at least 2 (including 2) ethylenically unsaturated groups.

Specific examples of the compound (B-1) having 1 ethylenically unsaturated group include, for instance, (meth)acrylamide, (meth)acryloylmorpholine, 7-amino-3,7-dimethyloctyl (meth)acrylate, isobutoxymethyl(meth)acrylamide, isobornyloxyethyl (meth)acrylate, isobornyl (meth)acrylate, 2-ethylhexyl(meth)acrylate, ethyl diethylene glycol(meth)acrylate, t-octyl(meth)acrylamide, diacetone(meth)acrylamide, dimethylaminoethyl(meth)acrylate, dodecyl(meth)acrylate, dicyclopentenyloxyethyl(meth)acrylate, dicyclopentenyl(meth)acrylate, N,N-dimethyl(meth)acrylamide, tetrachlorophenyl(meth)acrylate, 2-tetrachlorophenoxy ethyl(meth)acrylate, tetrahydrofurfuryl(meth)acrylate, tetrabromophenyl(meth)acrylate, 2-tetrabromophenoxyethyl(meth)acrylate, 2-trichlorophenoxyethyl(meth)acrylate, tribromophenyl(meth)acrylate, 2-tribromophenoxyethyl(meth)acrylate, ethyl 2-hydroxy-(meth)acrylate, propyl 2-hydroxy-(meth)acrylate, vinylcaprolactam, N-vinylpyrrolidone, phenoxyethyl(meth)acrylate, pentachlorophenyl(meth)acrylate, pentabromophenyl(meth)acrylate, polyethylene glycol mono(meth)acrylate, polypropylene glycol mono(meth)acrylate, and bornyl(meth)acrylate. The compound (B-1) having 1 ethylenically unsaturated group can be used alone or in a combination of two or more.

Specific examples of the compound (B-2) having at least 2 (including 2) ethylenically unsaturated groups include ethylene glycol di(meth)acrylate, dicyclopentenyl di(meth)acrylate, triethylene glycol di(meth)acrylate, tetraethylene glycol di(meth)acrylate, tri(2-hydroxyethyl)isocyanurate di(meth)acrylate, tri(2-hydroxyethyl)isocyanurate tri(meth)acrylate, caprolactone-modified tri(2-hydroxyethyl)isocyanurate tri(meth)acrylate, trimethylolpropyl tri(meth)acrylate, ethylene oxide (EO)modified trimethylolpropyl tri(meth)acrylate, propylene oxide (PO)modified trimethylolpropyl tri(meth)acrylate, tripropylene glycol di(meth)acrylate, neo-pentyl glycol di(meth)acrylate, 1,4-butanediol di(meth)acrylate, 1,6-hexanediol di(meth)acrylate, pentaerythritol tri(meth)acrylate, pentaerythritol tetra(meth)acrylate, polyester di(meth)acrylate, polyethylene glycol di(meth)acrylate, dipentaerythritol hexa(meth)acryl ate, dipentaerythritol penta(meth)acrylate, dipentaerythritol tetra(meth)acrylate, caprolactone-modified dipentaerythritol hexa(meth)acrylate, caprolactone-modified dipentaerythritol penta(meth)acrylate, di(trimethylolpropane)tetra(meth)acrylate, EO-modified bisphenol A di(meth)acrylate, PO-modified bisphenol A di(meth)acrylate, EO-modified hydrogenated bisphenol A di(meth)acrylate, PO-modified hydrogenated bisphenol A di(meth)acrylate, PO-modified glycerol triacrylate, EO-modified bisphenol F di(meth)acrylate, novolac polyglycidyl ether(meth)acrylate, a similar compound thereof, or a combination of the compounds. The compound (B-2) having at least 2 (including 2) ethylenically unsaturated groups can be used alone or in a combination of two or more.

Specific examples of the compound (B) containing an ethylenically unsaturated group include trimethylolpropyl triacrylate, EO-modified trimethylolpropyl triacrylate, PO-modified trimethylolpropyl triacrylate, pentaerythritol triacrylate, pentaerythritol tetraacrylate, dipentaerythritol hexaacrylate, dipentaerythritol pentaacrylate, dipentaerythritol tetraacrylate, caprolactone-modified dipentaerythritol hexaacrylate, ditrimethylolpropyl tetraacrylate, PO-modified glycerol triacrylate, a similar compound thereof, or a combination of the compounds.

The compound (B) containing an ethylenically unsaturated group is preferably trimethylolpropane triacrylate, dipentaerythritol tetracrylate, dipentaerythritol hexaacrylate, or a combination of the compounds.

Based on a usage amount of 100 parts by weight of the alkali-soluble resin (A), the usage amount of the compound (B) containing an ethylenically unsaturated group can be 20 parts by weight to 150 parts by weight, preferably 25 parts by weight to 130 parts by weight, and more preferably 30 parts by weight to 110 parts by weight.

### Photoinitiator (C)

The photoinitiator (C) is, for instance, an acetophenone compound, a biimidazole compound, an acyl oxime compound, or a combination of the compounds.

Specific examples of the acetophenone compound include p-dimethylamino-acetophenone, α,α′-dimethoxyazoxy-acetophenone, 2,2′-dimethyl-2-phenyl-acetophenone, p-methoxy-acetophenone, 2-methyl-1-(4-methylthio phenyl)-2-morpholino-1-propanone, 2-benzyl-2-N,N-dimethylamino-1-(4-morpholinophenyl)-1-butanone, or a combination of the compounds.

Specific examples of the biimidazole compound include 2,2′-bis(o-chlorophenyl)-4,4′,5,5′-tetraphenyl-biimidazole, 2,2′-bis(o -fluorophenyl)-4,4′,5,5′-tetraphenyl-biimidazole, 2,2′-bis(o-methyl phenyl)-4,4′,5,5′-tetraphenyl-biimidazole, 2,2′-bis(o-methoxyphenyl)-4,4′,5,5′-tetraphenyl-biimidazole, 2,2′-bis(o-ethylphenyl)-4,4′,5,5′-tetraphenyl-biimidazole, 2,2′-bis(p-methoxyphenyl)-4,4′,5,5′-tetraphenyl-biimidazole, 2,2′-bis(2,2′,4,4′-tetramethoxyphenyl)-4,4′,5,5′-tetraphenyl-biimidazole, 2,2′-bis(2-chlorophenyl)-4,4′,5,5′-tetraphenyl-biimidazole, 2,2′-bis(2,4-dichlorophenyl)-4,4′,5,5′-tetraphenyl-biimidazole, or a combination of the compounds.

Specific examples of the acyl oxime compound include ethanone, 1-[9-ethyl-6-(2-methylbenzoyl)-9H-carbazole-3-yl]-,1-(O-acetyl oxime) such as OXE-02 made by Ciba Specialty Chemicals having a structure represented by formula (7), 1-(4-phenyl-thio-phenyl)-octane-1,2-dion 2-oxime-O-benzoate such as OXE-01 made by Ciba Specialty Chemicals having a structure represented by formula (8), ethanone,1-[9-ethyl-6-(2-chloro-4-benzyl-thio-benzoyl)-9H-carbazole-3-yl]-,1-(O-acety 1 oxime) made by Asahi Denka Co., Ltd. having a structure represented by formula (9), or a combination of the compounds.

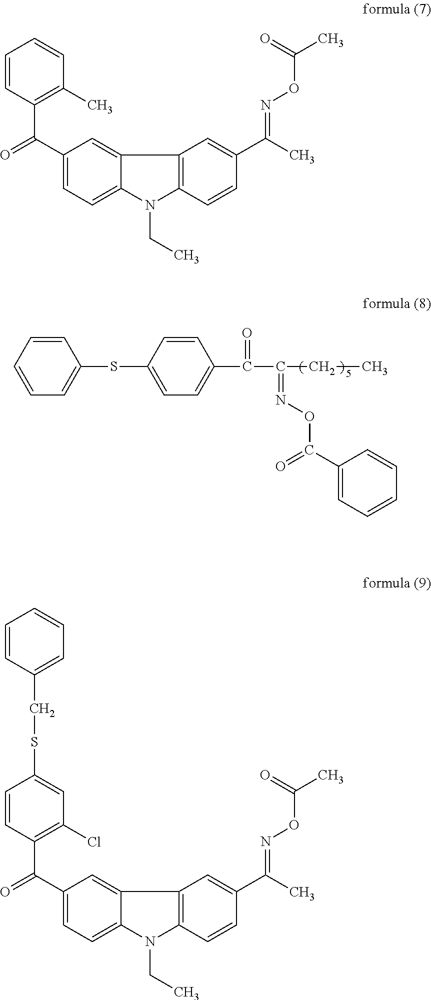

The photoinitiator (C) is preferably 2-methyl-1-(4-methylthio phenyl)-2-morpholino-1-propanone, 2-benzyl-2-N,N-dimethyl amino-1-(4-morpholinophenyl)-1-butanone, 2,2′-bis(o-chlorophenyl)-4,4′,5,5′-tetraphenyl-biimidazole, ethanone,1-[9-ethyl-6-(2-methylbenzoyl)-9H-carbazole-3-yl]-,1-(O-acetyl oxime), or a combination of the compounds.

The photoinitiator (C) can further include the following compounds as needed: a benzophenone compound such as thioxanthone, 2,4-diethyl-thioxanthanone, thioxanthone-4-sulfone, benzophenone, 4,4′-bis(dimethylamino)benzophenone, or 4,4′-bis(diethylamino)benzophenone; an α-diketone such as benzil or acetyl; an acyloin such as benzoin; an acyloin ether such as benzoin methylether, benzoin ethylether, or benzoin isopropyl ether; an acylphosphineoxide such as 2,4,6-trimethyl-benzoyl-diphenyl-phosphineoxide or bis-(2,6-dimethoxy-benzoyl)-2,4,4-trimethyl-benzyl-phosphineoxide; a quinone such as anthraquinone or 1,4-naphthoquinone; a halide such as phenacyl chloride, tribromomethyl-phenylsulfone, or tris(trichloromethyl)-s-triazine; a peroxide such as di-tert-butylperoxide, or a combination of the compounds. The compound added to the photoinitiator (C) is preferably a benzophenone compound, more preferably 4,4′-bis(diethylamino)benzophenone.

Based on a usage amount of 100 parts by weight of the alkali-soluble resin (A), the usage amount of the photoinitiator (C) can be 10 parts by weight to 90 parts by weight, preferably 12 parts by weight to 80 parts by weight, and more preferably 15 parts by weight to 70 parts by weight.

### Organic Solvent (D)

The organic solvent (D) refers to an organic solvent capable of dissolving the alkali-soluble resin (A), the compound (B) containing an ethylenically unsaturated group, and the photoinitiator (C), but does not react with the components, and preferably has a suitable volatility.

The organic solvent (D) is, for instance, a (poly)alkylene glycol monoalkyl ether, a (poly)alkylene glycol monoalkyl ether acetate, other ethers, a ketone, an alkyl lactate, other esters, an aromatic hydrocarbon compound, a carboxylic acid amide, or a combination of the solvents.

Specific examples of the (poly)alkylene glycol monoalkyl ether include ethylene glycol monomethyl ether, ethylene glycol monoethyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, tripropylene glycol monoethyl ether, or a combination of the solvents.

Specific examples of the (poly)alkylene glycol monoalkyl ether acetate include ethylene glycol monomethyl ether acetate, ethylene glycol monoethyl ether acetate, propylene glycol monomethyl ether acetate, propylene glycol monoethyl ether acetate, or a combination of the solvents.

Specific examples of the other ethers include diethylene glycol dimethyl ether, diethylene glycol methyl ethyl ether, diethylene glycol diethyl ether, tetrahydrofuran, or a combination of the solvents.

Specific examples of the ketone include methyl ethyl ketone, cyclohexanone, 2-heptanone, 3-heptanone, or a combination of the solvents.

Specific examples of the alkyl lactate include methyl 2-hydroxypropionate, ethyl 2-hydroxypropionate, or a combination of the solvents.

Specific examples of the other esters include methyl 2-hydroxy-2-methylpropionate, ethyl 2-hydroxy-2-methylpropionate, methyl 3-methoxypropionate, ethyl 3-methoxypropionate, methyl 3-ethoxypropionate, ethyl 3-ethoxypropionate(EEP), ethyl ethoxyacetate, ethyl hydroxyacetate, methyl 2-hydroxy-3-methylbutyrate, 3-methyl-3-methoxybutyl acetate, 3-methyl-3-methoxybutylpropionate, ethyl acetate, n-propyl acetate, isopropylacetate, n-butyl acetate, isobutyl acetate, n-pentyl acetate, isopentyl acetate, n-butyl propionate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, ethyl 2-oxybutyrate, or a combination of the solvents.

Specific examples of the aromatic hydrocarbon compound include toluene, xylene, or a combination of the solvents.

Specific examples of the carboxylic acid amide include N-methylpyrrolidone, N,N-dimethyl formamide, N,N-dimethyl acetamide, or a combination of the solvents.

The organic solvent (D) is preferably propylene glycol monomethyl ether acetate, EEP, or a combination of the solvents. The organic solvent (D) can be used alone or in a combination of two or more.

Based on a usage amount of 100 parts by weight of the alkali-soluble resin (A), the usage amount of the organic solvent (D) can be 1000 parts by weight to 7500 parts by weight, preferably 1200 parts by weight to 7000 parts by weight, and more preferably 1400 parts by weight to 6500 parts by weight.

### Colorant (E)

The photosensitive resin composition of the invention can further contain a colorant (E) as needed. When the photosensitive resin composition is used for forming a pixel layer, the colorant (E) can be a first colorant (E-1) used for forming the pixel layer. When the photosensitive resin composition is used for forming a black matrix, the colorant (E) can be a black pigment (E-2) used for forming the black matrix.

### First Colorant (E-1)

The first colorant (E-1) includes an inorganic pigment, an organic pigment, or a combination of the two.

Specific examples of the inorganic pigment include a metal compound (a metal oxide of, for instance, iron, cobalt, aluminum, cadmium, lead, copper, titanium, magnesium, chromium, zinc, or antimony) such as a metal oxide or a metallic complex salt and a composite oxide of the metals.

Specific examples of the organic pigment include C. I. pigment yellow 1, 3, 11, 12, 13, 14, 15, 16, 17, 20, 24, 31, 53, 55, 60, 61, 65, 71, 73, 74, 81, 83, 93, 95, 97, 98, 99, 100, 101, 104, 106, 108, 109, 110, 113, 114, 116, 117, 119, 120, 126, 127, 128, 129, 138, 139, 150, 151, 152, 153, 154, 155, 156, 166, 167, 168, 175; C. I. pigment orange 1, 5, 13, 14, 16, 17, 24, 34, 36, 38, 40, 43, 46, 49, 51, 61, 63, 64, 71, 73; C. I. pigment red 1, 2, 3, 4, 5, 6, 7, 8, 9, 10, 11, 12, 14, 15, 16, 17, 18, 19, 21, 22, 23, 30, 31, 32, 37, 38, 40, 41, 42, 48:1, 48:2, 48:3, 48:4, 49:1, 49:2, 50:1, 52:1, 53:1, 57, 57:1, 57:2, 58:2, 58:4, 60:1, 63:1, 63:2, 64:1, 81:1, 83, 88, 90:1, 97, 101, 102, 104, 105, 106, 108, 112, 113, 114, 122, 123, 144, 146, 149, 150, 151, 155, 166, 168, 170, 171, 172, 174, 175, 176, 177, 178, 179, 180, 185, 187, 188, 190, 193, 194, 202, 206, 207, 208, 209, 215, 216, 220, 224, 226, 242, 243, 245, 254, 255, 264, 265; C. I. pigment violet 1, 19, 23, 29, 32, 36, 38, 39; C. I. pigment blue 1, 2, 15, 15:3, 15:4, 15:6, 16, 22, 60, 66; C. I. pigment green 7, 36, 37; C. I. pigment brown 23, 25, 28, or a combination of the pigments.

### Black Pigment (E-2)

The black pigment (E-2) is preferably a black pigment having heat resistance, light resistance, and solvent resistance.

Specific examples of the black pigment (E-2) include: a black organic pigment such as perylene black, cyanine black, or aniline black; a near-black mixture of organic pigments obtained by mixing two or more pigments selected from the pigments of, for instance, red, blue, green, purple, yellow, cyanine, and magenta; a light-shielding material such as carbon black, chromium oxide, ferric oxide, titanium black, or graphite, wherein specific examples of the carbon black include C.I. pigment black 1 and 7 and a commercial product made by Mitsubishi Chemical (product name MA100, MA230, MA8, #970, #1000, #2350, or #2650). The black pigment (E-2) can be used alone or in a combination of two or more.

The black pigment (E-2) is preferably carbon black, and the carbon black is, for instance, the commercial product MA100 or MA230 made by Mitsubishi Chemical.

Based on a usage amount of 100 parts by weight of the alkali-soluble resin (A), the usage amount of the colorant (E) can be 50 parts by weight to 800 parts by weight, preferably 80 parts by weight to 700 parts by weight, and more preferably 100 parts by weight to 600 parts by weight.

### Additive (F)

Under the premise that the efficacy of the invention is not affected, the photosensitive resin composition of the invention can further optionally include an additive (F). Specific examples of the additive (F) include a surfactant, a filler, a polymer (other than the alkali-soluble resin (A)), an adhesion promoter, an antioxidant, an ultraviolet absorber, and an anti-coagulant.

The surfactant helps to improve the coating properties of the photosensitive resin composition. Specific examples of the surfactant include a cationic surfactant, an anionic surfactant, a nonionic surfactant, an amphoteric surfactant, a polysiloxane surfactant, a fluorine surfactant, or a combination of the surfactants.

Specifically, the surfactant is, for instance, a polyoxyethylene alkyl ether such as polyoxyethylene lauryl ether, polyoxyethylene stearyl amine ether, or polyoxyethylene oleyl ether; a polyoxyethylene alkyl phenyl ether such as polyoxyethylene octyl phenyl ether or polyoxyethylene nonyl phenyl ether; a polyethylene glycol diester such as polyethylene glycol dilaurate or polyethylene glycol distearate; a sorbitan fatty acid ester; a fatty acid-modified polyester; or tertiary amine-modified polyurethane. The surfactant can be used alone or in a combination of two or more.

Specific examples of the surfactant include a KP product made by Shin-Etsu Chemical Co., Ltd., an SF-8427 product made by Dow Corning Toray Co., Ltd., a Polyflow product made by Kyoeisha Chemical Co. Ltd., an F-Top product made by Tochem Products Co., Ltd., a Megafac product made by DIC Corporation, a Fluorade product made by Sumitomo 3M Limited, an Asahi Guard product made by Asahi Glass Co., Ltd., or a Surflon product made by Asahi Glass Co., Ltd.

Specific examples of the filler include, for instance, glass and aluminum.

Specific examples of the polymer include polyvinyl alcohol, polyethylene glycol monoalkyl ether, polyfluoro alkyl acrylate, or a combination of the polymers.

Specific examples of the adhesion promoter include vinyltrimethoxysilane, vinyltriethoxysilane, vinyl-tris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidolpropyltrimethoxysilane, 3-glycidolpropylmethyldiethoxysilane, 3-glycido 1propylmethyldimethoxysilane, 2-(3,4-epoxycyclohexyl)ethyltrimethoxysilane, 3-chloropropylmethyldimethoxysilane, 3-chloropropyltrimethoxysilane, 3-methacryloyloxy propyltrimethoxysilane, 3-mercaptopropyltrimethoxysilane, 3-glycidoxypropyltrimethoxysilane, or a combination of the compounds.

Specific examples of the antioxidant include 2,2-thiobis(4-methyl-6-t-butylphenol), 2,6-di-t-butylphenol, or a combination of the compounds.

Specific examples of the ultraviolet absorber include 2-(3-t-butyl-5-methyl-2-hydroxyphenyl)-5-chlorophenylazide, alkoxy phenone, or a combination of the compounds.

Specific examples of the anti-coagulant include, for instance, sodium polyacrylate.

Based on a usage amount of 100 parts by weight of the alkali-soluble resin (A), the usage amount of the additive (F) is 0.1 part by weight to 10 parts by weight, preferably 0.5 parts by weight to 8 parts by weight, and more preferably 1 parts by weight to 6 parts by weight.

### <Preparation Method of Photosensitive Resin Composition>

A method that can be used to prepare the photosensitive resin composition includes, for instance: placing and stirring the alkai-soluble resin (A), the compound (B) containing an ethylenically unsaturated group, the photoinitiator (C), and the organic solvent (D) in a stirrer such that the components are uniformly mixed into a solution state. When needed, one or both of the colorant (E) and the additive (F) can also be added. After the components are uniformly mixed, the photosensitive resin composition in a solution state can be obtained. Specifically, when the photosensitive resin composition is used for fanning a pixel layer, the colorant (E) can be a first colorant (E-1) used for forming the pixel layer. When the photosensitive resin composition is used for forming a black matrix, the colorant (E) can be a black pigment (E-2) used for forming the black matrix.

In addition, the method for preparing the photosensitive resin composition is not particularly limited. The method for preparing the photosensitive resin composition includes, for instance, first dispersing a portion of the alkali-soluble resin (A) and the compound (B) containing an ethylenically unsaturated group in a portion of the organic solvent (D) to form a dispersion solution, and then mixing the rest of the colorant (E), the alkali-soluble resin (A), the compound (B) containing an ethylenically unsaturated group, the photoinitiator (C), and the organic solvent (D).

Alternatively, the photosensitive resin composition can also be prepared by first dispersing a portion of the colorant (E) in a mixture composed of a portion of the alkali-soluble resin (A) and a portion of the organic solvent (D) to form a pigment dispersion solution, and then mixing the rest of the colorant (E), the alkali-soluble resin (A), the compound (B) containing an ethylenically unsaturated group, the photoinitiator (C), and the organic solvent (D). Moreover, the dispersion steps of the colorant (E) can be performed by mixing with a mixer such as a beads mill or a roll mill.

### <Method for Manufacturing Color Filter>

The method for manufacturing the color filter includes forming a black matrix, a pixel layer, a protective film, an ITO protective film, and a liquid crystal alignment film on a substrate in order. The methods for manufacturing the black matrix, the pixel layer, the protective film, the ITO protective film, and the liquid crystal alignment film using the photosensitive resin composition are respectively described below.

### 1. Method for Manufacturing Black Matrix

The black matrix is obtained by applying the treatments of pre-bake, exposure, development, and post-bake to the photosensitive resin composition containing the black pigment (E-2) in order. The black matrix is used for isolating each pixel layer. Moreover, when the film thickness of the black matrix is 1 μM, the range of the optical density can be at least 3.0, preferably 3.2 to 5.5, and more preferably 3.5 to 5.5. The method for manufacturing the black matrix is described below.

First, the photosensitive resin composition in liquid state is uniformly coated on a substrate by a coating method such as spin coating or cast coating to form a coating film. Specific examples of the substrate include alkali-free glass, soda-lime glass, hard glass (Pyrex glass), silica glass, and glasses with a transparent conductive film attached thereto used for a liquid crystal display apparatus. Alternatively, the substrate can be a substrate (such as a silicon substrate) used for a photoelectric conversion apparatus such as a solid imaging device.

After the coating film is formed, most of the solvent is removed by drying under reduced pressure. Next, the remaining solvent is completely removed by a pre-bake method to form a pre-baked coating film. It should be mentioned that, the conditions for drying under reduced pressure and pre-bake vary according to the type and ratio of each component. Generally, drying under reduced pressure is performed at a pressure less than 200 mmHg for 1 second to 20 seconds, and the pre-bake is a heat treatment performed on the coating film at a temperature of 70° C. to 110° C. for 1 minute to 15 minutes.

Then, the pre-baked coating film is exposed with a photomask having a specific pattern. The light used in the exposure process is preferably an ultraviolet light such as a g-ray, an h-ray, or an i-ray. In addition, the ultraviolet light irradiation apparatus can be a(n) (ultra-)high pressure mercury vapor lamp or a metal halide lamp.

Then, the exposed pre-baked coating film is immersed in a developing solution at a temperature of 23±2° C. to remove the unexposed portion of the pre-baked coating film and to form a specific pattern on the substrate.

The developing solution is, for instance, an alkali compound such as sodium hydroxide, potassium hydroxide, sodium carbonate, sodium hydrogen carbonate, potassium carbonate, potassium hydrogen carbonate, sodium silicate, sodium methyl silicate, ammonia solution, ethylamine, diethylamine, dimethylethylanolamine, tetramethylammonium hydroxide, tetraethylammonium hydroxide, choline, pyrrole, piperidine, or 1,8-diazabicyclo[5.4.0]-7-undecene. The concentration of the developing solution is generally 0.001 wt % to 10 wt %, preferably 0.005 wt % to 5 wt %, and more preferably 0.01 wt % to 1 wt %.

After the pre-baked coating film is developed, the substrate having a specific pattern is rinsed with water, and then the specific pattern is air dried with compressed air or compressed nitrogen. Then, a post-bake treatment is performed with a heating apparatus such as a hot plate or an oven. The post-bake temperature is generally 150 to 250° C., wherein when a hot plate is used, the heating time is 5 minutes to 60 minutes, and when an oven is used, the heating time is 15 minutes to 150 minutes. After the treatment steps, a black matrix can be formed on the substrate.

### 2. Method for Manufacturing Pixel Layer

The method for manufacturing the pixel layer is similar to the method for manufacturing the black matrix. Specifically, the pixel layer is obtained by coating the photosensitive composition containing the first colorant (E-1) on the substrate with a black matrix foamed thereon, and then applying the treatments of pre-bake, exposure, development, and post-bake in order. However, drying under reduced pressure is performed at a pressure of 0 mmHg to 200 mmHg for 1 second to 60 seconds. After the treatment steps, a specific pattern can be fixed, thereby forming the pixel layer. Moreover, the steps above are repeated to form pixel layers of, for instance, red, green, and blue on the substrate in order.

### 3. Method for Manufacturing Protective Film

The protective film is obtained by coating a photosensitive composition without the colorant (E) on the substrate with a black matrix and a pixel layer formed thereon, and then applying the treatments of pre-bake, exposure, and post-bake in order. The method for manufacturing the protective film is described below.

The photosensitive resin composition in liquid state is uniformly coated on the substrate with a black matrix and a pixel layer formed thereon to form a coating film. The coating method is, for instance, a spray method, a roller coating, a spin coating method, a bar coating method, or an ink jet method. The coating method can utilize a spin coater, a spinless coating machine, or a slit-die coating machine.

Then, pre-bake is performed on the coating film. The conditions for pre-bake vary according to the type of each component and the mixing ratio. In general, the pre-bake is performed at a temperature of 70° C. to 90° C. for 1 minute to 15 minutes. After the pre-bake, the thickness of the pre-baked coating film is 0.15 μm to 8.5 μm, preferably 0.15 μm to 6.5 μm, and more preferably 0.15 μm to 4.5 μm. The thickness of the pre-baked coating film is the thickness after the solvent is removed.

Then, an exposure treatment is performed on the pre-baked coating film. The light used for the exposure treatment is, for instance, visible light, ultraviolet light, far ultraviolet light, electron beam, or x-ray. However, ultraviolet light with a wavelength of 190 nm to 450 nm is preferred. The exposure amount of the exposure treatment can be 100 J/m² to 20,000 J/m², and is preferably 150 J/m² to 10,000 J/m².

Then, a heat treatment is performed on the pre-baked coating film after the exposure treatment with a heating apparatus such as a hot plate or an oven. The temperature of the heat treatment is generally 150° C. to 250° C. When a hot plate is used, the heating time is 5 minutes to 30 minutes, and when an oven is used, the heating time is 30 minutes to 90 minutes. After the treatment steps, a protective film can be formed on the substrate on which a black matrix and a pixel layer are formed.

### 4. Method for Manufacturing ITO Protective Film and Liquid Crystal Alignment Film

An ITO protective film (evaporated film) is formed on the surface of the pixel layer via sputtering in a vacuum environment at a temperature of 220° C. to 250° C. When needed, the ITO protective film is etched and wired, and a liquid crystal alignment film (polyimide for liquid crystal alignment film) is coated on the surface of the ITO protective film to form a color filter.

### <Method for Manufacturing Liquid Crystal Display Apparatus>

First, the color filter formed by the method for forming a color filter and a substrate provided with a thin film transistor (TFT) are disposed opposite to each other, and a gap (cell gap) is left between the two. Then, the color filter and the peripheral portion of the substrate are laminated with an adhesive and an injection hole is left. Then, liquid crystal is injected into the gap separated by the substrate surface and the adhesive through the injection hole. Lastly, the injection hole is sealed to form a liquid crystal layer. Then, a polarizer is provided to each of the other side of the color filter in contact with the liquid crystal layer and the other side of the substrate in contact with the liquid crystal layer to fabricate the liquid crystal display. The liquid crystal used, i.e., a liquid crystal compound or a liquid crystal composition, is not particularly limited. Any liquid crystal compound or liquid crystal composition can be used.

Moreover, the liquid crystal alignment film used in the fabrication of the color filter is used to limit the alignment of the liquid crystal molecules and is not particularly limited. Both inorganic matter and organic matter can be used, and the invention is not limited thereto.

### PREPARATION EXAMPLES OF DIOL COMPOUND (a-1) CONTAINING A POLYMERIC UNSATURATED GROUP

Preparation example 1 to preparation example 6 of the diol compound (a-1) containing a polymeric unsaturated group are described below:

### Preparation Example 1

First, 100 parts by weight of a fluorene epoxy compound (model number: ESF-300, made by Nippon Steel Chemical, epoxy equivalent: 231), 30 parts by weight of acrylic acid, 0.3 parts by weight of benzyltriethylammonium chloride, 0.1 parts by weight of 2,6-di-tert-butyl-p-cresol, and 130 parts by weight of propylene glycol monomethyl ether acetate were added in a 500 ml four-neck flask in a continuous manner. The feeding speed was controlled at 25 parts by weight/minute, the temperature of the reaction process was maintained at 100° C. to 110° C., and the mixture was reacted for 15 hours to obtain a light yellow transparent mixture solution having a solid content of 50 wt %. Then, steps of extraction, filtration, and heating and drying were performed on the light yellow transparent mixture solution to obtain a diol compound (a-1-1) containing a polymeric unsaturated group of preparation example 1 having a solid content of 99.9 wt %.

### Preparation Example 2

First, 100 parts by weight of a fluorene epoxy compound (model number: PG-100, made by Osaka Gas, epoxy equivalent: 259), 35 parts by weight of methacrylic acid, 0.3 parts by weight of benzyltriethylammonium chloride, 0.1 parts by weight of 2,6-di-tert-butyl-p-cresol, and 135 parts by weight of propylene glycol monomethyl ether acetate were added in a 500 ml four-neck flask in a continuous manner. The feeding speed was controlled at 25 parts by weight/minute, the temperature of the reaction process was maintained at 100° C. to 110° C., and the mixture was reacted for 15 hours to obtain a light yellow transparent mixture solution having a solid content of 50 wt %. Steps of extraction, filtration, and heating and drying were performed on the light yellow transparent mixture solution to obtain a diol compound (a-1-2) containing a polymeric unsaturated group of preparation example 2 having a solid content of 99.9 wt %.

### Preparation Example 3

100 parts by weight of a fluorene epoxy compound (model number: ESF-300, made by Nippon Steel Chemical, epoxy equivalent: 231), 100 parts by weight of 2-methacryloyl oxyethyl succinate, 0.3 parts by weight of benzyltriethylammonium chloride, 0.1 parts by weight of 2,6-di-tert-butyl-p-cresol, and 200 parts by weight of propylene glycol monomethyl ether acetate were added in a 500 ml four-neck flask in a continuous manner. The feeding speed was controlled at 25 parts by weight/minute, the temperature of the reaction process was maintained at 100° C. to 110° C., and the mixture was reacted for 15 hours to obtain a light yellow transparent mixture solution having a solid content of 50 wt %. Steps of extraction, filtration, and heating and drying were performed on the light yellow transparent mixture solution to obtain a diol compound (a-1-3) containing a polymeric unsaturated group of preparation example 3 having a solid content of 99.9 wt %.

### Preparation Example 4

First, 0.3 moles of bis(4-hydroxyphenyl)sulfone, 9 moles of epichlorohydrin, and 0.003 moles of tetramethyl ammonium chloride were added in a 1000 mL three-neck flask provided with a mechanical stirrer, a thermometer, and a reflux condenser. Next, the flask was heated to 105° C. while stirring and reacted at 105° C. for 9 hours. Then, unreacted epichlorohydrin was distilled under reduced pressure. Next, the reaction system was cooled to room temperature and 9 moles of benzene and 0.5 moles of sodium hydroxide (30 wt % aqueous solution formed by dissolving in water) were added thereto while stirring. Then, the temperature was raised to 60° C. and maintained at 60° C. for 3 hours. Next, the reaction solution was washed with water repeatedly until no chloride ions remained (tested with silver nitrate). The solvent benzene was removed via distillation under reduced pressure, and then the reaction solution was dried at 75° C. for 24 hours to obtain an epoxy compound of bis(4-hydroxyphenyl)sulfone.

100 parts by weight of an epoxy compound (epoxy equivalent: 181) of bis(4-hydroxyphenyl)sulfone, 30 parts by weight of acrylic acid, 0.3 parts by weight of benzyltriethylammonium chloride, 0.1 parts by weight of 2,6-di-tert-butyl-p-cresol, and 130 parts by weight of propylene glycol monomethyl ether acetate were added in a 500 ml four-neck flask in a continuous manner. The feeding speed was controlled at 25 parts by weight/minute, the temperature of the reaction process was maintained at 100° C. to 110° C., and the mixture was reacted for 15 hours to obtain a light yellow transparent mixture solution having a solid content of 50 wt %. Steps of extraction, filtration, and heating and drying were performed on the light yellow transparent mixture solution to obtain a diol compound (a-1-4) containing a polymeric unsaturated group of preparation example 4 having a solid content of 99.9 wt %.

### Preparation Example 5

0.3 moles of bis(4-hydroxyphenyl)hexafluoropropane, 9 moles of epichlorohydrin, and 0.003 moles of tetramethyl ammonium chloride were added in a 1000 mL three-neck flask provided with a mechanical stirrer, a thermometer, and a reflux condenser. Next, the flask was heated to 105° C. while stirring and reacted at 105° C. for 9 hours. Then, unreacted epichlorohydrin was distilled under reduced pressure. Next, the reaction system was cooled to room temperature and 9 moles of benzene and 0.5 moles of sodium hydroxide (30 wt % aqueous solution formed by dissolving in water) were added thereto while stirring. Then, the temperature was raised to 60° C. and maintained at 60° C. for 3 hours. Next, the reaction solution was washed with water repeatedly until no chloride ions remained (tested with silver nitrate). The solvent benzene was removed via distillation under reduced pressure, and then the reaction solution was dried at 75° C. for 24 hours to obtain an epoxy compound of bis(4-hydroxyphenyl)hexafluoropropane.

100 parts by weight of an epoxy compound (epoxy equivalent: 224) of bis(4-hydroxyphenyl)hexafluoropropane, 35 parts by weight of methacrylic acid, 0.3 parts by weight of benzyltriethylammonium chloride, 0.1 parts by weight of 2,6-di-tert-butyl-p-cresol, and 135 parts by weight of propylene glycol monomethyl ether acetate were added in a 500 ml four-neck flask in a continuous manner. The feeding speed was controlled at 25 parts by weight/minute, the temperature of the reaction process was maintained at 100° C. to 110° C., and the mixture was reacted for 15 hours to obtain a light yellow transparent mixture solution having a solid content of 50 wt %. Steps of extraction, filtration, and heating and drying were performed on the light yellow transparent mixture solution to obtain a diol compound (a-1-5) containing a polymeric unsaturated group of preparation example 5 having a solid content of 99.9 wt %.

### Preparation Example 6

0.3 moles of bis(4-hydroxyphenyl)dimethylsilane, 9 moles of epichlorohydrin, and 0.003 moles of tetramethyl ammonium chloride were added in a 1000 mL three-neck flask provided with a mechanical stirrer, a thermometer, and a reflux condenser. Next, the flask was heated to 105° C. while stirring and reacted at 105° C. for 9 hours. Then, unreacted epichlorohydrin was distilled under reduced pressure. Next, the reaction system was cooled to room temperature and 9 moles of benzene and 0.5 moles of sodium hydroxide (30 wt % aqueous solution formed by dissolving in water) were added thereto while stirring. Then, the temperature was raised to 60° C. and maintained at 60° C. for 3 hours. Next, the reaction solution was washed with water repeatedly until no chloride ions remained (tested with silver nitrate). The solvent benzene was removed via distillation under reduced pressure, and then the reaction solution was dried at 75° C. for 24 hours to obtain an epoxy compound of bis(4-hydroxyphenyl)dimethylsilane.

100 parts by weight of an epoxy compound (epoxy equivalent: 278) of bis(4-hydroxyphenyl)dimethylsilane, 100 parts by weight of 2-methacryloyl oxyethyl succinate, 0.3 parts by weight of benzyltriethylammonium chloride, 0.1 parts by weight of 2,6-di-tert-butyl-p-cresol, and 200 parts by weight of propylene glycol monomethyl ether acetate were added in a 500 ml four-neck flask in a continuous manner. The feeding speed was controlled at 25 parts by weight/minute, the temperature of the reaction process was maintained at 100° C. to 110° C., and the mixture was reacted for 15 hours to obtain a light yellow transparent mixture solution having a solid content of 50 wt %. Steps of extraction, filtration, and heating and drying were performed on the light yellow transparent mixture solution to obtain a diol compound (a-1-6) containing a polymeric unsaturated group of preparation example 6 having a solid content of 99.9 wt %.

### SYNTHESIS EXAMPLES OF FIRST ALKAI-SOLUBLE RESIN A-1

In the following, synthesis example 1 to synthesis example 10 of the first alkali-soluble resin A-1 are described:

### Synthesis Example 1

First, 1.0 mole of the diol compound containing a polymeric unsaturated group (a-1-1), 0.1 moles of 4,4′-hexafluoro isopropylidene diphthalic dianhydride (a-2-1-a), 0.2 moles of pyromellitic dianhydride (a-2-2-c), 0.4 moles of maleic acid (a-3-2-a), 1.0 mole of tetrahydrophthalic anhydride (a-3-2-b), 1.9 grams of benzyltriethylammonium chloride, 0.6 grams of 2,6-di-tert-butyl-p-cresol, and 750 grams of propylene glycol monomethyl ether acetate were added to a 500 mL four-neck flask at the same time to form a reaction solution. Here, “simultaneous addition” refers to adding the tetracarboxylic acid or an acid dianhydride thereof (a-2) and the dicarboxylic acid or an acid anhydride thereof (a-3) at the same reaction time. Then, the reaction solution was heated to 110° C. and reacted for 2 hours to obtain the first alkali-soluble resin (referred to as the first alkali-soluble resin A-1-1 below) of synthesis example 1 having an acid value of 129 mgKOH/g and a number-average molecular weight of 2368.

### Synthesis Example 2

1.0 mole of the diol compound (a-1-2) containing a polymeric unsaturated group, 2.0 grams of benzyltriethylammonium chloride, 0.7 grams of 2,6-di-tert-butyl-p-cresol, and 700 grams of propylene glycol monomethyl ether acetate were added to a 500 mL four-neck flask to form a reaction solution. Then, 0.2 moles of 1,4-difluoropyromellitic dianhydride (a-2-1-b) and 0.2 moles of benzophenone tetracarboxylic dianhydride (a-2-2-b) were added and the mixture was reacted at 90° C. for 2 hours. Then, 1.2 moles of tetrahydrophthalic anhydride (a-3-2-b) was added and the mixture was reacted at 90° C. for 4 hours. Here, “successive addition” refers to respectively adding the tetracarboxylic acid or an acid dianhydride thereof (a-2) and the dicarboxylic acid or an acid anhydride thereof (a-3) at different reaction times. That is, the tetracarboxylic acid or an acid dianhydride thereof (a-2) is added first, and the dicarboxylic acid or an acid anhydride thereof (a-3) is added afterward. After the synthesis steps, the first alkali-soluble resin (referred to as the first alkali-soluble resin A-1-2 below) of synthesis example 2 having an acid value of 125 mgKOH/g and a number-average molecular weight of 3388 can be obtained.

### Synthesis Example 3, Synthesis Example 5, Synthesis Example 7, and Synthesis Example 9

The first alkali-soluble resins of synthesis example 3, synthesis example 5, synthesis example 7, and synthesis example 9 were prepared with the same steps as synthesis example 1, and the difference is: the type, the usage amount, the reaction time, the reaction temperature, and the addition time of the reactants of the components of the first alkali-soluble resins were changed (as shown in Table 1), wherein the compounds corresponding to the labels in Table 1 are as follows.

### Synthesis Example 4, Synthesis Example 6, Synthesis Example 8, and Synthesis Example 10

The first alkali-soluble resins of synthesis example 4, synthesis example 6, synthesis example 8, and synthesis example 10 were prepared with the same steps as synthesis example 2, and the difference is: the type, the usage amount, the reaction time, the reaction temperature, and the addition time of the reactants of the components of the first alkali-soluble resins were changed (as shown in Table 1), wherein the compounds corresponding to the labels in Table 1 are as follows.

| Abbreviation | Component |
|---|---|
| a-1-1 | Diol compound (a-1-1) containing a polymeric unsaturated |
| | group of preparation example 1 |
| a-1-2 | Diol compound (a-1-2) containing a polymeric unsaturated |
| | group of preparation example 2 |
| a-1-3 | Diol compound (a-1-3) containing a polymeric unsaturated |
| | group of preparation example 3 |
| a-1-4 | Diol compound (a-1-4) containing a polymeric unsaturated |
| | group of preparation example 4 |
| a-1-5 | Diol compound (a-1-5) containing a polymeric unsaturated |
| | group of preparation example 5 |
| a-1-6 | Diol compound (a-1-6) containing a polymeric unsaturated |
| | group of preparation example 6 |
| a-2-1-a | 4,4′-hexafluoro isopropylidene diphthalic |
| | dianhydride (6FDA) |
| a-2-1-b | 1,4-difluoropyromellitic dianhydride |
| a-2-1-c | 1,4-di(trifluoromethyl)pyromellitic dianhydride |
| a-2-1-d | 1,4-bis(3,4-dicarboxytrifluorophenoxy)tetrafluoro |
| | benzenedianhydride |
| a-2-2-a | Biphenyl tetracarboxylic acid |
| a-2-2-b | Benzophenone tetracarboxylic dianhydride |
| a-2-2-c | Pyromellitic dianhydride |
| a-3-1-a | 3-fluorophthalic anhydride |
| a-3-1-b | 3,6-difluorophthalic anhydride |
| a-3-1-c | 4-fluorophthalic anhydride |
| a-3-1-d | Tetrafluorobutanedioic anhydride |
| a-3-2-a | Maleic acid |
| a-3-2-b | Tetrahydrophthalic anhydride |
| a-3-2-c | Trimethoxysilyl propyl succinic anhydride |
| PGMEA | Propylene glycol monomethyl ether acetate (PGMEA) |
| EEP | Ethyl 3-ethoxypropionate (EEP) |
| — | Benzyltriethylammonium chloride |
| — | 2,6-di-tert-butyl-p-cresol |

TABLE 1

| | | | | Synthesis example | | | | |
|---|---|---|---|---|---|---|---|---|
| Component | | | | 1 | 2 | 3 | 4 | 5 |
| First alkali-soluble resin | | | | A-1-1 | A-1-2 | A-1-3 | A-1-4 | A-1-5 |
| Polymeric | Diol compound (a-1) containing a | | a-1-1 | 1.0 | — | — | — | — |
| component | polymeric unsaturated group (moles) | | a-1-2 | — | 1.0 | — | — | — |
| | | | a-1-3 | — | — | 1.0 | — | — |
| | | | a-1-4 | — | — | — | 1.0 | — |
| | | | a-1-5 | — | — | — | — | 1.0 |
| | | | a-1-6 | — | — | — | — | — |
| | Tetracarboxylic | Tetracarboxylic | a-2-1-a | 0.1 | — | — | — | — |
| | acid or acid | acid or an acid | a-2-1-b | — | 0.2 | — | — | — |
| | dianhydride | dianhydride thereof | a-2-1-c | — | — | 0.1 | — | — |
| | thereof (a-2) | (a-2-1) containing a | a-2-1-d | — | — | 0.2 | 0.6 | — |
| | | fluorine atom | | | | | | |
| | | Other | a-2-2-a | — | — | 0.3 | — | 0.4 |
| | | tetracarboxylic | a-2-2-b | — | 0.2 | — | — | — |
| | | acids or an acid | a-2-2-c | 0.2 | — | — | — | — |
| | | dianhydride thereof | | | | | | |
| | | (a-2-2) | | | | | | |
| | Dicarboxylic acid | Dicarboxylic acid | a-3-1-a | — | — | — | — | 1.2 |
| | or an acid | or an acid | a-3-1-b | — | — | — | — | — |
| | anhydride thereof | anhydride thereof | a-3-1-c | — | — | — | — | — |
| | (a-3) | (a-3-1) containing a | a-3-1-d | — | — | — | — | — |
| | | fluorine atom | | | | | | |
| | | Other dicarboxylic | a-3-2-a | 0.4 | — | — | 0.8 | — |
| | | acids or an acid | a-3-2-b | 1.0 | 1.2 | 0.8 | — | — |
| | | anhydride thereof | a-3-2-c | — | — | — | — | — |
| | | (a-3-2) | | | | | | |
| Monomer input method | | | | simultaneous | successive | simultaneous | successive | simultaneous |
| | | | | addition | addition | addition | addition | addition |
| Catalyst | Benzyltriethylammonium chloride (grams) | | | 1.9 | 2.0 | 2.9 | 1.1 | 1.3 |
| Inhibitor | 2,6-di-tert-butyl-p-cresol (grams) | | | 0.6 | 0.7 | 1.0 | 0.4 | 0.4 |
| Solvent | PGMEA (grams) | | | 750 | 700 | 1000 | — | 650 |
| | EEP (grams) | | | — | — | 100 | 650 | — |
| [(a-2-1) + (a-3-1)]/(a-1) | | | | 0.1 | 0.2 | 0.3 | 0.6 | 1.2 |
| Reaction temperature (° C.) | | | | 110 | 90 | 115 | 95 | 110 |
| Reaction time (hours) | | | | 2 | 2 | 1.5 | 1.5 | 2 |
| | | | | | 4 | | 4 | |
| Acid value (mgKOH/g) | | | | 129 | 125 | 87 | 139 | 144 |
| Number-average molecular weight (Mn) | | | | 2368 | 3388 | 4965 | 5201 | 3665 |
| | | | | Synthesis example | | | | |
| Component | | | | 6 | 7 | 8 | 9 | 10 |
| First alkali-soluble resin | | | | A-1-6 | A-1-7 | A-1-8 | A-1-9 | A-1-10 |
| Polymeric | Diol compound (a-1) containing a | | a-1-1 | — | 1.0 | — | 0.5 | — |
| component | polymeric unsaturated group (moles) | | a-1-2 | — | — | — | — | 0.5 |
| | | | a-1-3 | — | — | 1.0 | 0.3 | 0.5 |
| | | | a-1-4 | — | — | — | 0.2 | — |
| | | | a-1-5 | — | — | — | — | — |
| | | | a-1-6 | 1.0 | — | — | — | — |
| | Tetracarboxylic | Tetracarboxylic acid | a-2-1-a | — | — | — | 0.2 | — |
| | acid or acid | or an acid | a-2-1-b | — | — | — | — | — |
| | dianhydride | dianhydride thereof | a-2-1-c | — | — | — | — | — |
| | thereof (a-2) | (a-2-1) containing a | a-2-1-d | — | — | — | — | 0.3 |
| | | fluorine atom | | | | | | |
| | | Other | a-2-2-a | — | — | — | 0.5 | — |
| | | tetracarboxylic acids | a-2-2-b | 0.1 | — | — | — | 0.5 |
| | | or an acid | a-2-2-c | — | 0.1 | — | — | — |
| | | dianhydride thereof | | | | | | |
| | | (a-2-2) | | | | | | |
| | Dicarboxylic acid | Dicarboxylic acid or | a-3-1-a | — | 1.2 | — | — | — |
| | or an acid | an acid anhydride | a-3-1-b | 1.6 | — | — | 0.6 | — |
| | anhydride thereof | thereof (a-3-1) | a-3-1-c | — | 0.6 | — | — | 0.2 |
| | (a-3) | containing a fluorine | a-3-1-d | — | — | 1.9 | — | — |
| | | atom | | | | | | |
| | | Other dicarboxylic | a-3-2-a | — | — | — | — | 0.2 |
| | | acids or an acid | a-3-2-b | 0.2 | — | 0.1 | — | — |
| | | anhydride thereof | a-3-2-c | — | — | — | — | — |
| | | (a-3-2) | | | | | | |

| Monomer input method | | successive | simultaneous | successive | simultaneous | successive |
|---|---|---|---|---|---|---|
| | | addition | addition | addition | addition | addition |
| Catalyst | Benzyltriethylammonium chloride (grams) | 1.1 | 1.9 | 2.9 | 2.0 | 2.4 |
| Inhibitor | 2,6-di-tert-butyl-p-cresol (grams) | 0.4 | 0.6 | 1.0 | 0.7 | 0.8 |
| Solvent | PGMEA (grams) | 600 | 800 | 1100 | — | 100 |
| | EEP (grams) | — | — | — | 850 | 900 |

| | | | | | |
|---|---|---|---|---|---|
| [(a-2-1) + (a-3-1)]/(a-1) | 1.6 | 1.8 | 1.9 | 0.8 | 0.5 |
| Reaction temperature (° C.) | 90 | 115 | 95 | 110 | 90 |
| Reaction time (hours) | 2 | 1.5 | 2 | 2 | 2 |
| | 3.5 | | 3.5 | | 4 |
| Acid value (mgKOH/g) | 159 | 113 | 87 | 108 | 93 |
| Number-average molecular weight (Mn) | 1885 | 1732 | 1250 | 6023 | 6802 |

### SYNTHESIS EXAMPLES OF SECOND ALKAI-SOLUBLE RESIN (A-2)

In the following, synthesis example 11 to synthesis example 13 of the second alkali-soluble resin (A-2) are described:

### Synthesis Example 11

1.0 mole of the diol compound (a-1-1) containing a polymeric unsaturated group, 1.9 grams of benzyltriethylammonium chloride, and 0.6 grams of 2,6-di-tert-butyl-p-cresol were dissolved in 700 grams of propylene glycol methyl ether acetate, and 0.3 moles of biphenyl tetracarboxylic acid (a-2-2-a) and 1.4 moles of maleic acid (a-3-2-a) were added at the same time. Then, the mixture was heated to 110° C. and reacted for 2 hours to obtain the second alkali-soluble resin (referred to as the second alkali-soluble resin A-2-1 below) of synthesis example 11 having an acid value of 125 mgKOH/g and a number-average molecular weight of 2455.

### Synthesis Example 12 to Synthesis Example 13

The second alkali-soluble resins of synthesis example 12 to synthesis example 13 were prepared with the same steps as synthesis example 11, and the difference is: the type, the usage amount, the reaction time, the reaction temperature, and the addition time of the reactants of the components of the second alkali-soluble resins were changed (as shown in Table 2). It should be mentioned that, here, “simultaneous addition” refers to adding the tetracarboxylic acid or an acid dianhydride thereof (a-2) and the dicarboxylic acid or an acid anhydride thereof (a-3) at the same reaction time, and “successive addition” refers to respectively adding the tetracarboxylic acid or an acid dianhydride thereof (a-2) and the dicarboxylic acid or an acid anhydride thereof (a-3) at different reaction times. That is, the tetracarboxylic acid or an acid dianhydride thereof (a-2) is added first, and the dicarboxylic acid or an acid anhydride thereof (a-3) is added afterward.

TABLE 2

| | | | | Synthesis example | | |
|---|---|---|---|---|---|---|
| Component | | | | 11 | 12 | 13 |
| Second alkali-soluble resin | | | | A-2-1 | A-2-1 | A-2-3 |
| Polymeric | Diol compound (a-1) containing a polymeric unsaturated | | a-1-1 | 1.0 | — | — |
| component | group (moles) | | a-1-2 | — | — | — |
| | | | a-1-3 | — | 1.0 | — |
| | | | a-1-4 | — | — | — |
| | | | a-1-5 | — | — | 1.0 |
| | | | a-1-6 | — | — | — |
| | Tetracarboxylic acid or | Tetracarboxylic acid or an acid | a-2-1-a | — | — | — |
| | acid dianhydride thereof | dianhydride thereof (a-2-1) | a-2-1-b | — | — | — |
| | (a-2) | containing a fluorine atom | a-2-1-c | — | — | — |
| | | a-2-1-d | — | — | — | |
| | | Other tetracarboxylic acids or an | a-2-2-a | 0.3 | — | — |
| | | acid dianhydride thereof (a-2-2) | a-2-2-b | — | 0.6 | — |
| | | | a-2-2-c | — | — | 0.8 |
| | Dicarboxylic acid or an | Dicarboxylic acid or an acid | a-3-1-a | — | — | — |
| | acid anhydride thereof | anhydride thereof (a-3-1) | a-3-1-b | — | — | — |
| | (a-3) | containing a fluorine atom | a-3-1-c | — | — | — |
| | | | a-3-1-d | — | — | — |
| | | Other dicarboxylic acids or an acid | a-3-2-a | 1.4 | — | — |
| | | anhydride thereof (a-3-2) | a-3-2-b | — | 0.8 | — |
| | | | a-3-2-c | — | — | 0.4 |

| Monomer input method | | simultaneous | successive | successive |
|---|---|---|---|---|
| | | addition | addition | addition |
| Catalyst | Benzyltriethylammonium chloride (grams) | 1.9 | 2.9 | 1.3 |
| Inhibitor | 2,6-di-tert-butyl-p-cresol (grams) | 0.6 | 0.0 | 0.0 |
| Solvent | PGMEA (grams) | 700 | 950 | 550 |
| | EEP (grams) | — | — | — |

| | | | |
|---|---|---|---|
| (a-2)/(a-1) | 0 | 0 | 0 |
| (a-3)/(a-1) | 0 | 0 | 0 |
| Reaction temperature (° C.) | 110 | 90 | 115 |
| Reaction time (hours) | 2 | 2 | 1.5 |
| | | 4 | |
| Acid value (mgKOH/g) | 125 | 92 | 164 |
| Number-average molecular weight (Mn) | 2455 | 5130 | 6542 |

### SYNTHESIS EXAMPLES OF OTHER ALKAI-SOLUBLE RESINS (A-3)

In the following, synthesis example 14 to synthesis example 16 of the other alkali-soluble resins (A-3) are described:

### Synthesis Example 14

A nitrogen inlet, a stirrer, a heater, a condenser tube, and a thermometer were provided to a four-neck round bottom flask having a volume of 1000 ml. After nitrogen was introduced, 15 parts by weight of acrylic acid (AA), 15 parts by weight of 2-hydroxyethyl methacrylate (HEMA), 10 parts by weight of benzyl methacrylate (BzMA), 60 parts by weight of CF9BuMA, 3 parts by weight of 2,2′-azobis(2-methylbutyronitrile) (AMBN), and 300 parts by weight of diethylene glycol dimethyl ether (diglyme) were added. Then, the mixture was slowly stirred and the solution was heated to 80° C. Then, polycondensation was performed on the mixture at 80° C. for 6 hours. Then, after the solvent was evaporated, an alkali-soluble resin (A-3-1) can be obtained.

### Synthesis Example 15 to Synthesis Example 16

The other alkali-soluble resins of synthesis example 15 to synthesis example 16 were prepared with the same steps as synthesis example 11, and the difference is: the type, the usage amount, the reaction time, the reaction temperature, and the addition time of the reactants of the components of the other alkali-soluble resins were changed (as shown in Table 3), wherein the compounds corresponding to the labels in Table 3 are as follows.

| Abbreviation | Component |
|---|---|
| AMBN | 2,2′-azobis-2-methyl butyronitrile |
| ADVN | 2,2′-azobis(2,4-dimethylvaleronitrile) |
| MAA | Methacrylic acid |
| AA | acrylic acid |
| GMA | Glycidyl methacylate |
| HEMA | 2-hydroxyethyl methacrylate |
| BzMA | Benzyl methacrylate |
| IBOMA | Isobornyl methacrylate |
| CF9BuMA | CH₂═C(CH₃)COOCH₂CH₂CH₂CH₂OC₉F₁₇ |
| CF9PEMA | CH₂═C(CH₃)COOCH₂CH₂OCOC₆H₄OC₉F₁₇ |
| Diglyme | Diethylene glycol dimethyl ether |
| PGMEA | Propylene glycol monomethyl ether acetate |

TABLE 3

| | | Synthesis example | | |
|---|---|---|---|---|
| Component | | 14 | 15 | 16 |
| Other alkali-soluble resin | | A-3-1 | A-3-2 | A-3-3 |
| Monomer | MAA | — | 20 | 10 |
| (parts by | AA | 15 | — | 20 |
| weight) | GMA | — | — | 10 |
| | HEMA | 15 | 10 | — |
| | BzMA | 10 | — | 20 |
| | IBOMA | — | 10 | 40 |
| Monomer | CF9BuMA | 60 | — | — |
| containing | CF9PEMA | — | 60 | — |
| fluorine (parts | | | | |
| by weight) | | | | |
| Solvent (parts | Diglyme | 300 | — | 300 |
| by weight) | PGMEA | — | 300 | — |
| Initiator (parts | AMBN | 3.0 | 3.0 | — |
| by weight) | ADVN | — | — | 2.0 |

| | | | |
|---|---|---|---|
| Reaction temperature (° C.) | 80 | 80 | 80 |
| Polycondensation time (hours) | 6 | 6 | 6 |

### EXAMPLES OF PHOTOSENSITIVE RESIN

Example 1 to example 10 and comparative example 1 to comparative example 7 of the photosensitive resin are described below:

### Example 1

100 parts by weight of the first alkali-soluble resin (A-1-1), 20 parts by weight of trimethylolpropane triacrylate (B-1), and 10 parts by weight of ethanone,1-[9-ethyl-6-(2-methylbenzoyl)-9H-carbazole-3-yl]-,1-(O-acetyl oxime)(C-1) were added to 1000 parts by weight of propylene glycol monomethyl ether acetate (D-1) and uniformly stirred with a shaking type stirrer to obtain the photosensitive resin composition of example 1. The obtained photosensitive resin composition was evaluated by each of the following evaluation methods, and the results are as shown in Table 4.

### Example 2 to Example 10

The photosensitive resin compositions of example 2 to example 10 were prepared using the same steps as example 1, with the difference being: the type and the usage amount of the components of the photosensitive resin compositions were changed (as shown in Table 4), wherein the compounds corresponding to the labels of Table 4 are as shown below. The obtained photosensitive resin compositions were evaluated by each of the following evaluation methods, and the results are as shown in Table 4.

| Abbreviation | Component |
|---|---|
| B-1 | Trimethylolpropane triacrylate |
| B-2 | Dipentaerythritol tetracrylate |
| B-3 | Dipentaerythritol hexacrylate |
| C-1 | Ethanone, 1-[9-ethyl-6-(2-methylbenzoyl)-9H-carbazole-3- |
| | yl]-,1-(O-acetyl oxime) (product name: OXE-02, made by |
| | Ciba Specialty Chemicals) |
| C-2 | 1-(4-phenyl-thio-phenyl)-octane-1,2-dion-2-oxime-O- |
| | benzoate (product name: OXE-01, made by Ciba Specialty |
| | Chemicals) |
| C-3 | 2-methyl-1-[4-(methylthio)phenyl]-2-morpholino-1- |
| | propanone (product name: IRGACURE 907, made by Ciba |
| | Specialty Chemicals Co., Ltd.) |
| D-1 | Propylene glycol monomethyl ether acetate |
| D-2 | Ethyl 3-ethoxypropionate |
| E-1-1 | C.I. Pigment R254/C.I. Pigment Y139 = 80/20 |
| E-1-2 | C.I. Pigment G36/C.I. Pigment Y150 = 60/40 |
| E-1-3 | C.I. Pigment B15:6 |
| E-2-1 | C.I. Pigment BK7 |
| E-2-2 | MA100 (made by Mitsubishi Chemical) |
| G-1 | SF-8427 (made by Dow Corning Toray Co., Ltd., |
| | surfactant) |
| G-2 | 3-glycidoxypropyltrimethoxysilane (product name: |
| | KBM403, made by Shin-Etsu Chemical, adhesion |
| | promoter) |

TABLE 4

| | | | Example | | | | | | | | | |
|---|---|---|---|---|---|---|---|---|---|---|---|---|
| Component | | | 1 | 2 | 3 | 4 | 5 | 6 | 7 | 8 | 9 | 10 |
| Alkai-soluble resin (A) | A-1 | A-1-1 | 100 | — | — | — | — | — | — | — | 20 | — |
| (parts by weight) | | A-1-2 | — | 100 | — | — | — | — | — | — | — | — |
| | | A-1-3 | — | — | 90 | — | — | — | — | — | — | — |
| | | A-1-4 | — | — | — | 50 | — | — | — | — | — | — |
| | | A-1-5 | — | — | — | — | 100 | — | — | — | — | — |
| | | A-1-6 | — | — | — | — | — | 100 | 50 | — | — | — |
| | | A-1-7 | — | — | — | — | — | — | 50 | — | — | — |
| | | A-1-8 | — | — | — | — | — | — | — | 70 | — | — |
| | | A-1-9 | — | — | — | — | — | — | — | — | 30 | — |
| | | A-1-10 | — | — | — | — | — | — | — | — | — | 30 |
| | A-2 | A-2-1 | — | — | 10 | — | — | — | — | — | 40 | — |
| | | A-2-2 | — | — | — | 50 | — | — | — | — | — | — |
| | | A-2-3 | — | — | — | — | — | — | — | 20 | — | 70 |
| | A-3 | A-3-1 | — | — | — | — | — | — | — | — | 10 | — |
| | | A-3-2 | — | — | — | — | — | — | — | — | — | — |
| | | A-3-3 | — | — | — | — | — | — | — | 20 | — | — |
| Compound (B) containing an | B-1 | | 20 | — | — | 80 | — | — | 150 | 30 | — | — |
| ethylenically unsaturated | B-2 | | — | 40 | — | — | 100 | — | — | — | 60 | — |
| group | B-3 | | — | — | 50 | — | — | 120 | — | 70 | — | 90 |
| (parts by weight) | | | | | | | | | | | | |
| Photoinitiator (C) | C-1 | | 10 | — | — | 30 | 10 | — | 55 | — | — | — |
| (parts by weight) | C-2 | | — | 20 | — | — | — | 40 | — | 70 | — | — |
| | C-3 | | — | — | 25 | — | 20 | — | — | — | 80 | 90 |
| Organic solvent (D) | D-1 | | 1000 | — | 2000 | 2000 | 3500 | — | 5000 | 5000 | 6000 | 2500 |
| (parts by weight) | D-2 | | — | 1500 | — | 500 | — | 4000 | — | 1000 | — | 5000 |
| Colorant (E) | E-1 | E-1-1 | — | 50 | — | — | — | — | 200 | — | — | — |
| (parts by weight) | | E-1-2 | — | — | 80 | — | — | — | — | — | — | — |
| | | E-1-3 | — | — | — | — | — | 150 | — | — | — | — |
| | E-2 | E-2-1 | — | — | — | 100 | — | — | — | 500 | — | — |
| | | E-2-2 | — | — | — | — | 350 | — | — | — | 800 | — |

| | | | | | | | | | | | |
|---|---|---|---|---|---|---|---|---|---|---|---|
| Additive (F) | G-1 | — | 1 | — | — | — | — | — | — | — | — |
| (parts by weight) | G-2 | — | — | — | — | — | — | 2 | — | — | — |
| Evaluation results | Resolution | ◯ | ⊚ | ⊚ | ⊚ | ⊚ | ⊚ | ⊚ | ◯ | ⊚ | ⊚ |
| | Development | ⊚ | ⊚ | ⊚ | ⊚ | ⊚ | ⊚ | ⊚ | ⊚ | ⊚ | ⊚ |
| | resistance | | | | | | | | | | |

### Comparative Example 1 to Comparative Example 7

The photosensitive resin compositions of comparative example 1 to comparative example 7 were prepared using the same steps as example 1, and the difference is: the type and the usage amount of the components of the photosensitive resin compositions were changed (as shown in Table 5). The obtained photosensitive resin compositions were evaluated by each of the following evaluation methods, and the results are as shown in Table 5.

TABLE 5

| | | | Comparative example | | | | | |
|---|---|---|---|---|---|---|---|---|
| Component | | | 1 | 2 | 3 | 4 | 5 | 6 |
| Alkai-soluble resin (A) | A-1 | A-1-1 | — | — | — | — | — | — |
| (parts by weight) | | A-1-2 | — | — | — | — | — | — |
| | | A-1-3 | — | — | — | — | — | — |
| | | A-1-4 | — | — | — | — | — | — |
| | | A-1-5 | — | — | — | — | — | — |
| | | A-1-6 | — | — | — | — | — | — |
| | | A-1-7 | — | — | — | — | — | — |
| | | A-1-8 | — | — | — | — | — | — |
| | | A-1-9 | — | — | — | — | — | — |
| | | A-1-10 | — | — | — | — | — | — |
| | A-2 | A-2-1 | 100 | — | — | — | — | — |
| | | A-2-2 | — | 100 | — | — | — | — |
| | | A-2-3 | — | — | 100 | — | — | — |
| | A-3 | A-3-1 | — | — | — | 100 | — | — |
| | | A-3-2 | — | — | — | — | 100 | — |
| | | A-3-3 | — | — | — | — | — | 100 |
| Compound (B) containing an | B-1 | | 50 | 80 | — | — | 80 | 100 |
| ethylenically unsaturated | B-2 | | — | — | 100 | — | — | — |
| group | B-3 | | — | — | — | 120 | — | — |
| (parts by weight) | | | | | | | | |
| Photoinitiator (C) | C-1 | | 20 | — | — | — | — | 50 |
| (parts by weight) | C-2 | | — | 30 | — | 40 | 30 | — |
| | C-3 | | — | — | 40 | — | — | — |
| Organic solvent (D) | D-1 | | 2500 | 3500 | — | 5000 | 3500 | — |
| (parts by weight) | D-2 | | — | — | 4000 | — | — | 5000 |
| Colorant (E) (parts by weight) | E-1 | E-1-1 | — | 80 | — | — | — | — |
| | | E-1-2 | — | — | 100 | — | — | — |
| | | E-1-3 | — | — | — | 150 | — | — |
| | E-2 | E-2-1 | — | — | — | — | 250 | — |
| | | E-2-2 | — | — | — | — | — | 300 |

| | | | | | | | |
|---|---|---|---|---|---|---|---|
| Additive (F) (parts by weight) | G-1 | — | — | — | — | — | — |
| | G-2 | — | — | — | — | — | — |
| Evaluation results | Resolution | X | X | X | X | X | X |
| | Development | X | X | X | X | X | X |
| | resistance | | | | | | |

### <Evaluation Methods>

### Resolution

The photosensitive resin composition obtained in each example and comparative example was coated on a glass substrate with a spin coating method. Then, the glass substrate was pre-baked at 100° C. for 2 minutes to obtain a pre-baked coating film of about 1.2 μm. Then, the pre-baked coating film was placed under a line and space photomask (made by Nibbon Filcon, Japan) and exposed with an ultraviolet light (model of exposure machine: AG500-4N, made by M&R Nano Technology) at 50 mJ/cm². Then, the pre-baked coating film was developed with a 0.045% aqueous solution of potassium hydroxide at 23° C. for 1 minute to remove the unexposed portion of the coating film on the substrate. Then, the glass substrate having a specific pattern was rinsed with water. Lastly, the minimum value of the line width magnitude of the pattern formed on the glass substrate was defined as the resolution. The line width magnitude was evaluated with the following methods. It should be mentioned that, a smaller minimum pattern line width represents better resolution of the photosensitive resin composition.
⊚: minimum pattern line width≧4 μm
∘: 4 μm<minimum pattern line width≧6 μm
Δ: 6 μm <minimum pattern line width≧8 μm
×: 8 μm<minimum pattern line width

### Development Resistance

The photosensitive resin composition of each example and comparative example was placed in a coating machine (purchased from Hsin Kuang Trade Co., Ltd.; model number: MS-A150), and the photosensitive resin compositions were coated on a 100 mm×100 mm glass substrate with a spin coating method. Then, drying under reduced pressure was performed at a pressure of 60 Pa for 15 seconds to Rhin a coating film. Then, the substrate having a coating film thereon was placed in an oven and pre-baked at a temperature of 100° C. for 2 minutes to form a pre-baked coating film. Then, exposure was performed on the pre-baked coating film with an ultraviolet light at 50 mJ/cm² (model of exposure machine: AG500-4N; made by M&R Nano Technology). At this point, the film thickness of the pre-baked coating film (photosensitive resin layer) before development can be measured. Then, the exposed pre-baked coating film was immersed in a developing solution (0.045% potassium hydroxide) at 23° C. for 1 minute to form a glass substrate having a developed coating film thereon. Then, the glass substrate having a developed coating film thereon was rinsed with water. Then, the glass substrate having a developed coating film thereon was placed in an oven and post-baked at 235° C. for 30 minutes to form a photosensitive resin layer on the glass substrate. At this point, the film thickness of the photosensitive resin layer after development can be measured. Then, the film thickness ratio before and after development was calculated with formula (I) by using the film thickness of the photosensitive resin layer before development and the film thickness of the photosensitive resin layer after development. Moreover, the film thickness ratio was evaluated with the following methods. It should be mentioned that, a greater film thickness ratio represents better development resistance of the photosensitive resin composition.

Film thickness ratio (before and after development)=(film thickness after development/film thickness before development)×100%
⊚: film thickness ratio≧88%
∘: 85% film thickness ratio<88%
Δ: 80%<film thickness ratio<85%
×: 80%<film thickness ratio

### <Evaluation Results>

It can be known from Table 4 and Table 5 that, in comparison to the photosensitive resin compositions (comparative example 1 to comparative example 3) containing only the second alkali-soluble resin (A-2) and the photosensitive resin compositions (comparative example 4 to comparative example 6) containing only the other alkali-soluble resins (A-3), the resolution and the development resistance of the photosensitive resin compositions (example 1 to example 10) containing the first alkali-soluble resin (A-1) (alkali soluble resin containing an aromatic structure having fluorine) are both better.

Moreover, when the number of moles of the diol compound (a-1) containing a polymeric unsaturated group, the number of moles of the tetracarboxylic acid or an acid dianhydride thereof (a-2-1) containing a fluorine atom, and the number of moles of the dicarboxylic acid or an acid anhydride thereof (a-3-1) containing a fluorine atom in the first alkali-soluble resin (A-1) satisfy the relationship [(a-2-1)+(a-3-1)]/(a-1)=0.2-1.8 (i.e., examples 2, 3, 4, 5, 6, 7, 9, and 10), the resolution of the photosensitive resin compositions is particularly good.

Based on the above, since the photosensitive resin composition of the invention contains an alkali-soluble resin having an aromatic structure having fluorine and a specific structure, the photosensitive resin composition has the features of resolution and development resistance, and is therefore suitable for the manufacture of a black matrix, a pixel layer, and a protective film of a color filter.

Although the invention has been described with reference to the above embodiments, it will be apparent to one of the ordinary skill in the art that modifications to the described embodiments may be made without departing from the spirit of the invention. Accordingly, the scope of the invention is defined by the attached claims not by the above detailed descriptions.

What is claimed is:

1. An alkali-soluble resin (A-1), represented by formula (1): 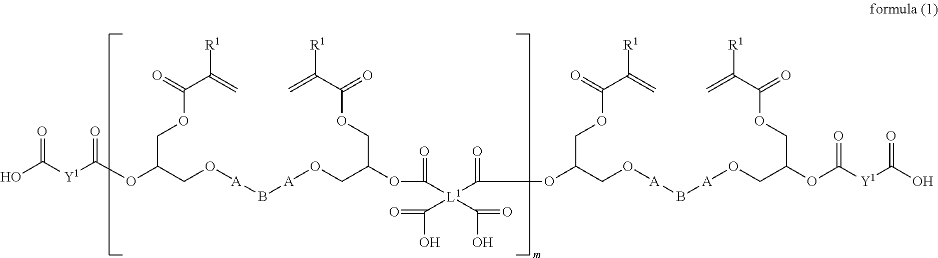
in formula (1), A represents a phenylene group or a phenylene group having a substituent, wherein the substituent is a C₁ to C₅ alkyl group, a halogen atom, or a phenyl group; B represents —CO—, —SO₂—, —C(CF₃)₂—, —Si(CH₃)₂—, —CH₂—, —C(CH₃)₂—, —O—, 9,9-fluorenylidene, or a single bond; L¹ represents a tetravalent carboxylic acid residue containing a fluorine atom or a tetravalent carboxylic acid residue without a fluorine atom; Y¹ represents a divalent carboxylic acid residue containing a fluorine atom or a divalent carboxylic acid residue without a fluorine atom; R¹ represents a hydrogen atom or a methyl group; m represents an integer of 1 to 20; and at least one of L¹ and Y¹ contains a fluorine atom.

2. The alkali-soluble resin (A-1) of claim 1, wherein the alkali-soluble resin (A-1) is obtained by reacting a first mixture, the first mixture comprising:
a diol compound (a-1) containing a polymeric unsaturated group;
a tetracarboxylic acid or an acid dianhydride thereof (a-2); and
a dicarboxylic acid or an acid anhydride thereof (a-3),
wherein the tetracarboxylic acid or an acid dianhydride thereof (a-2) comprises a tetracarboxylic acid or an acid dianhydride thereof (a-2-1) containing a fluorine atom, other tetracarboxylic acids or an acid dianhydride thereof (a-2-2) other than the tetracarboxylic acid or an acid dianhydride thereof (a-2-1) containing a fluorine atom, or a combination of the two;
the dicarboxylic acid or an acid anhydride thereof (a-3) comprises a dicarboxylic acid or an acid anhydride thereof (a-3-1) containing a fluorine atom, other dicarboxylic acids or an acid anhydride thereof (a-3-2) other than the dicarboxylic acid or an acid anhydride thereof (a-3-1) containing a fluorine atom, or a combination of the two;
at least one of the tetracarboxylic acid or an acid dianhydride thereof (a-2) and the dicarboxylic acid or an acid anhydride thereof (a-3) contains a fluorine atom.

3. The alkali-soluble resin (A-1) of claim 2, wherein the tetracarboxylic acid or an acid dianhydride thereof (a-2-1) containing a fluorine atom is selected from the group consisting of a tetracarboxylic acid compound containing a fluorine atom represented by formula (2-1) and a tetracarboxylic acid dianhydride compound containing a fluorine atom represented by formula (2-2), 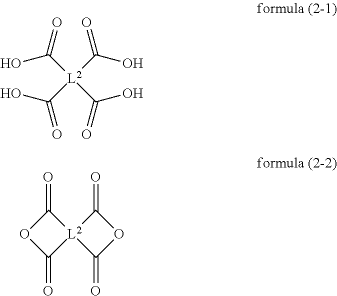
in formula (2-1) and formula (2-2), L² is selected from one of the groups represented by formula (L-1) to formula (L-6), 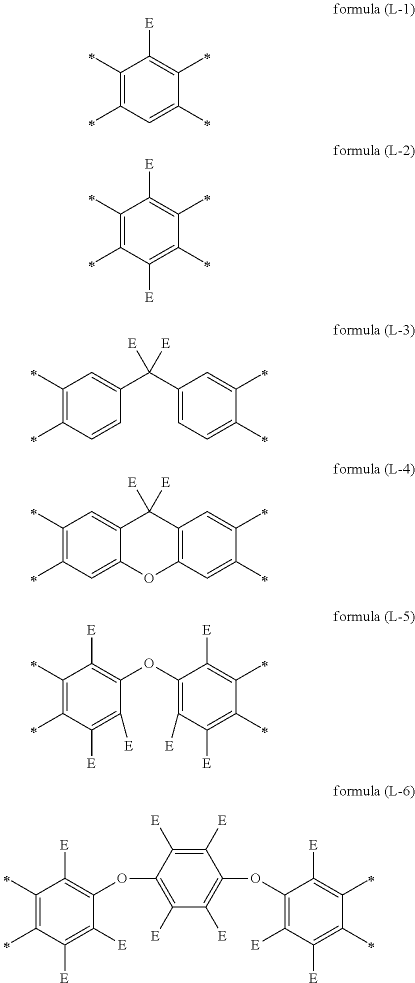
in formula (L-1) to formula (L-6), E each independently represents a fluorine atom or a trifluoromethyl group, and * represents the location of bonding with a carbon atom.

4. The alkali-soluble resin (A-1) of claim 2, wherein the dicarboxylic acid or an acid anhydride thereof (a-3-1) containing a fluorine atom is selected from the group consisting of a dicarboxylic acid compound containing a fluorine atom represented by formula (3-1) and a dicarboxylic acid anhydride compound containing a fluorine atom represented by formula (3-2), 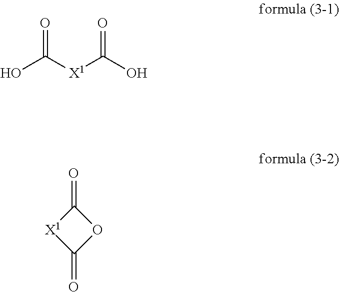
in formula (3-1) and formula (3-2), X¹ represents a C₁ to C₁₀₀ organic group containing a fluorine atom.

5. The alkali-soluble resin (A-1) of claim 2, wherein a number of moles of the diol compound (a-1) containing a polymeric unsaturated group, a number of moles of the tetracarboxylic acid or an acid dianhydride thereof (a-2-1) containing a fluorine atom, and a number of moles of the dicarboxylic acid or an acid anhydride thereof (a-3-1) containing a fluorine atom satisfy a relationship [(a-2-1)+(a-3-1)]/(a-1)=0.2-1.8.

6. The alkali-soluble resin (A-1) of claim 2, wherein a number of moles of the diol compound (a-1) containing a polymeric unsaturated group, a number of moles of the tetracarboxylic acid or an acid dianhydride thereof (a-2-1) containing a fluorine atom, and a number of moles of the dicarboxylic acid or an acid anhydride thereof (a-3-1) containing a fluorine atom satisfy a relationship [(a-2-1)+(a-3-1)]/(a-1)=0.3-1.7.

7. The alkali-soluble resin (A-1) of claim 2, wherein a number of moles of the diol compound (a-1) containing a polymeric unsaturated group, a number of moles of the tetracarboxylic acid or an acid dianhydride thereof (a-2-1) containing a fluorine atom, and a number of moles of the dicarboxylic acid or an acid anhydride thereof (a-3-1) containing a fluorine atom satisfy a relationship [(a-2-1)+(a-3-1)]/(a-1)=0.4-1.6.

8. A photosensitive resin composition, comprising:
an alkai-soluble resin (A);
a compound (B) containing an ethylenically unsaturated group;
a photoinitiator (C); and
an organic solvent (D),
wherein the alkali-soluble resin (A) comprises a first alkali-soluble resin (A-1) represented by formula (1); 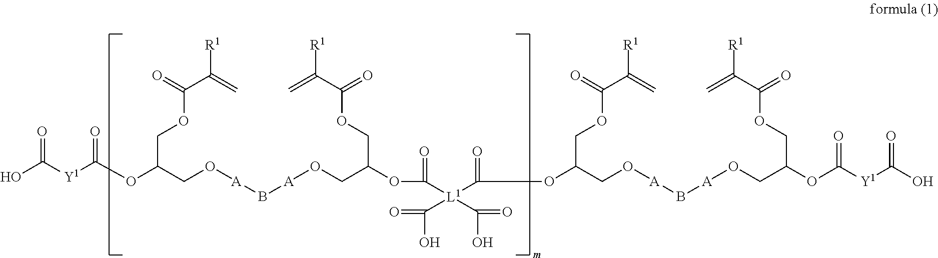
in formula (1), A represents a phenylene group or a phenylene group having a substituent, wherein the substituent is a C₁ to C₅ alkyl group, a halogen atom, or a phenyl group; B represents —CO—, —SO₂—, —C(CF₃)₂—, —Si(CH₃)₂—, —CH₂—, —C(CH₃)₂—, —O—, 9,9-fluorenylidene, or a single bond; L¹ represents a tetravalent carboxylic acid residue containing a fluorine atom or a tetravalent carboxylic acid residue without a fluorine atom; Y¹ represents a divalent carboxylic acid residue containing a fluorine atom or a divalent carboxylic acid residue without a fluorine atom; R¹ represents a hydrogen atom or a methyl group; m represents an integer of 1 to 20; and at least one of L¹ and Y¹ contains a fluorine atom.

9. The photosensitive resin composition of claim 8, wherein the first alkali-soluble resin (A-1) represented by formula (1) is obtained by reacting a first mixture, the first mixture comprising:
a diol compound (a-1) containing a polymeric unsaturated group;
a tetracarboxylic acid or an acid dianhydride thereof (a-2); and
a dicarboxylic acid or an acid anhydride thereof (a-3),
wherein the tetracarboxylic acid or an acid dianhydride thereof (a-2) comprises a tetracarboxylic acid or an acid dianhydride thereof (a-2-1) containing a fluorine atom, other tetracarboxylic acids or an acid dianhydride thereof (a-2-2) other than the tetracarboxylic acid or an acid dianhydride thereof (a-2-1) containing a fluorine atom, or a combination of the two;
the dicarboxylic acid or an acid anhydride thereof (a-3) comprises a dicarboxylic acid or an acid anhydride thereof (a-3-1) containing a fluorine atom, other dicarboxylic acids or an acid anhydride thereof (a-3-2) other than the dicarboxylic acid or an acid anhydride thereof (a-3-1) containing a fluorine atom, or a combination of the two;
at least one of the tetracarboxylic acid or an acid dianhydride thereof (a-2) and the dicarboxylic acid or an acid anhydride thereof (a-3) contains a fluorine atom.

10. The photosensitive resin composition of claim 9, wherein the tetracarboxylic acid or an acid dianhydride thereof (a-2-1) containing a fluorine atom is selected from the group consisting of a tetracarboxylic acid compound containing a fluorine atom represented by formula (2-1) and a tetracarboxylic acid dianhydride compound containing a fluorine atom represented by formula (2-2), 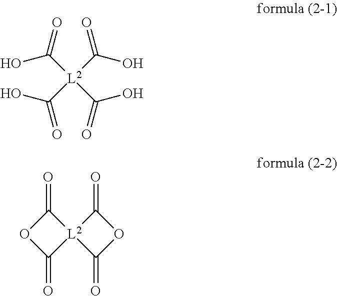
in formula (2-1) and formula (2-2), L² is selected from one of the groups represented by formula (L-1) to formula (L-6), 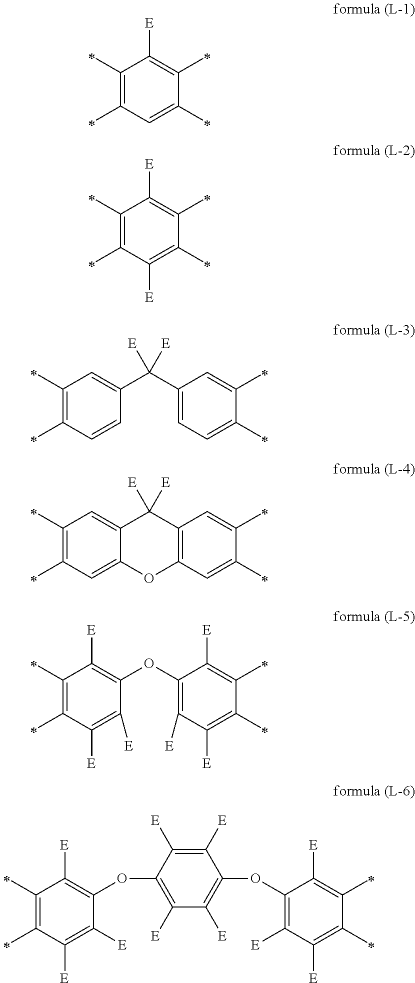
in formula (L-1) to formula (L-6), E each independently represents a fluorine atom or a trifluoromethyl group, and * represents the location of bonding with a carbon atom.

11. The photosensitive resin composition of claim 9, wherein the dicarboxylic acid or an acid anhydride thereof (a-3-1) containing a fluorine atom is selected from the group consisting of a dicarboxylic acid compound containing a fluorine atom represented by formula (3-1) and a dicarboxylic acid anhydride compound containing a fluorine atom represented by formula (3-2), 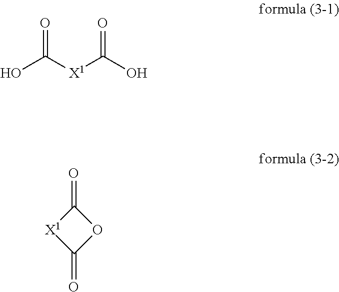
in formula (3-1) and formula (3-2), X¹ represents a C₁ to C₁₀₀ organic group containing a fluorine atom.

12. The photosensitive resin composition of claim 9, wherein a number of moles of the diol compound (a-1) containing a polymeric unsaturated group, a number of moles of the tetracarboxylic acid or an acid dianhydride thereof (a-2-1) containing a fluorine atom, and a number of moles of the dicarboxylic acid or an acid anhydride thereof (a-3-1) containing a fluorine atom satisfy a relationship [(a-2-1)+(a-3-1)]/(a-1)=0.2-1.8.

13. The photosensitive resin composition of claim 9, wherein a number of moles of the diol compound (a-1) containing a polymeric unsaturated group, a number of moles of the tetracarboxylic acid or an acid dianhydride thereof (a-2-1) containing a fluorine atom, and a number of moles of the dicarboxylic acid or an acid anhydride thereof (a-3-1) containing a fluorine atom satisfy a relationship [(a-2-1)+(a-3-1)]/(a-1)=0.3-1.7.

14. The photosensitive resin composition of claim 9, wherein a number of moles of the diol compound (a-1) containing a polymeric unsaturated group, a number of moles of the tetracarboxylic acid or an acid dianhydride thereof (a-2-1) containing a fluorine atom, and a number of moles of the dicarboxylic acid or an acid anhydride thereof (a-3-1) containing a fluorine atom satisfy a relationship [(a-2-1)+(a-3-1)]/(a-1)=0.4-1.6.

15. The photosensitive resin composition of claim 8, wherein based on a usage amount of 100 parts by weight of the alkai-soluble resin (A), a usage amount of the first alkali-soluble resin (A-1) is 30 parts by weight to 100 parts by weight, a usage amount of the compound (B) containing an ethylenically unsaturated group is 20 parts by weight to 150 parts by weight, a usage amount of the photoinitiator (C) is 10 parts by weight to 90 parts by weight, and a usage amount of the organic solvent (D) is 1000 parts by weight to 7500 parts by weight.

16. The photosensitive resin composition of claim 8, further comprising a colorant (E).

17. The photosensitive resin composition of claim 16, wherein based on a usage amount of 100 parts by weight of the alkali-soluble resin (A), a usage amount of the colorant (E) is 50 parts by weight to 800 parts by weight.

18. A method for manufacturing a color filter, comprising forming a black matrix by using the photosensitive resin composition of claim 8.

19. A method for manufacturing a color filter, comprising forming a pixel layer by using the photosensitive resin composition of claim 8.

20. A method for manufacturing a color filter, comprising forming a protective film by using the photosensitive resin composition of claim 8.

21. A color filter obtained by the method of claim 18.

22. A color filter obtained by the method of claim 19.

23. A color filter obtained by the method of claim 20.

24. A liquid crystal display apparatus, comprising the color filter of claim 21.

25. A liquid crystal display apparatus, comprising the color filter of claim 22.

26. A liquid crystal display apparatus, comprising the color filter of claim 23.
